(19) United States
(12) Patent Application Publication
(10) Pub. No.: US 2011/0254165 A1
(43) Pub. Date: Oct. 20, 2011

(54) SEMICONDUCTOR INTEGRATED CIRCUIT DEVICE AND PRODUCTION METHOD THEREOF

(75) Inventor: Seiji MURANAKA, Kanagawa (JP)

(73) Assignee: Renesas Electronics Corporation

(21) Appl. No.: 13/086,043

(22) Filed: Apr. 13, 2011

(30) Foreign Application Priority Data
Apr. 19, 2010 (JP) 2010-095779

(51) Int. Cl. H01L 23/532; H01L 21/768

(52) U.S. Cl. 257/751; 438/637; 257/E23.161; 257/E21.584

(57) ABSTRACT

In processes after a TSV is formed, occasionally, cracks appear in an insulation film after the insulation film that is a film for preventing Cu from diffusing is formed and the exposed Cu discolors at a succeeding process of pattern forming such as etching or asking. It is estimated that the problems occur because the volume of Cu expands by heat history at the process of forming a diffusion preventive film. When such film cracking occurs, various problems such as the destruction of the function of a Cu diffusion preventive film and conduction fault with upper wiring caused by the oxidation of Cu at the upper part of a TSV are induced. In the invention of the present application, in a semiconductor integrated circuit device having a through electrode, when a through via is formed after a pre-metal wiring layer is formed, an insulation film of a kind of silicon nitride is used as a metal diffusion preventive insulation film at the interface of an interlayer insulation film touching the top end of the through electrode and an insulation film of kind of silicon carbide is used as a metal diffusion preventive insulation film at the interfaces of the other interlayer insulation films.

### CROSS-REFERENCE TO RELATED APPLICATIONS

The disclosure of Japanese Patent Application No. 2010-95779 filed on Apr. 19, 2010 including the specification, drawings and abstract is incorporated herein by reference in its entirety.

### BACKGROUND

The present invention relates to: a semiconductor integrated circuit device (or a semiconductor device); and a technology effective when it is applied to a technology for preventing impurities of metals such as copper from diffusing in the production method of the semiconductor integrated circuit device (or the semiconductor device).

Japanese Unexamined Patent Publication No. 2007-335450 (Patent literature 1) or U.S. Patent Publication No. 2007-287298 (Patent literature 2) corresponding thereto discloses a technology of using SiCN, SiCO, SiC, S₃N₄, or the like as a copper diffusion preventive insulation film at the uppermost part of a lower layer wiring (single damascene interconnect) and using SiO₂, S₃N₄, or the like as a copper diffusion preventive insulation film in order to inhibit damages caused by asking or the like at the uppermost part of an upper layer wiring (dual damascene interconnect) in an interlayer insulation film structure (including an intralayer insulation film) of each of wiring layers in a copper-embedded wiring.

### PRIOR TECHNICAL LITERATURE

### Patent Literature

[Patent literature 1]
Japanese Unexamined Patent Publication No. 2007-335450
[Patent literature 2]
U.S. Patent Publication No. 2007-287298

### SUMMARY

A TSV (Through Silicon Via) process is studied with the aim of improving the integration of a semiconductor element by three-dimensional application, increasing the speed of signal transmission between chips, and applying to a high-frequency device. When Cu is used as the embedding material of a TSV, since the thinning of a wafer and the embedding performance of the TSV are limited, it is currently necessary to use a large diameter pattern of several tens of micrometers or more. An appropriate aspect ratio, the aspect ratio being the ratio of the depth to the size of a TSV, is generally about 3 or less and, if the aspect ratio is not less than 3, the possibility increases that the incidence of embedding failure increases because of problem on the coverage of a sputter film formed before Cu plating.

In processes after a TSV is formed, occasionally, cracks appear in an insulation film after the insulation film that is a film for preventing Cu from diffusing is formed and the exposed Cu discolors at a succeeding process of pattern forming such as etching or asking. It is estimated that the problems occur because the volume of Cu expands by heat history at the process of forming a diffusion preventive film.

When such film cracking occurs, various problems such as the destruction of the function of a Cu diffusion preventive film, conduction fault with upper wiring caused by the oxidation of Cu at the upper part of a TSV, and resolution fault caused by the occurrence of unevenness at a succeeding lithography process are induced. Further, there is a possibility that various drawbacks such as the appearance of foreign matters originated from abnormal parts and the deterioration of a product yield occur. The problems must be solved in order to put a TSV into practical use.

The present applied invention is established in order to solve the problems.

An object of the present invention is to provide a production process of a highly reliable semiconductor integrated circuit device.

The aforementioned and other objects and novel features of the present invention will be obvious from the descriptions and attached drawings of the present specification.

The representative outline of the invention disclosed in the present application is briefly explained as follows.

That is, in the invention of the present application, in a semiconductor integrated circuit device having a through electrode, when a through via is formed after a pre-metal wiring layer is formed, an insulation film of a kind of silicon nitride is used as a metal diffusion preventive insulation film at the interface of an interlayer insulation film touching the top end of the through electrode and an insulation film of a kind of silicon carbide is used as a metal diffusion preventive insulation film at the interfaces of the other interlayer insulation films.

The representative effects of the invention disclosed in the present application are briefly explained as follows.

That is, in a semiconductor integrated circuit device having a through electrode, when a through via is formed after a pre-metal wiring layer is formed, it is possible to provide a highly reliable device by using an insulation film of a kind of silicon nitride as a metal diffusion preventive insulation film at the interface of an interlayer insulation film touching the top end of the through electrode and an insulation film of a kind of silicon carbide as a metal diffusion preventive insulation film at the interfaces of the other interlayer insulation films.

### BRIEF DESCRIPTION OF THE DRAWINGS

FIG. 1 is an overall top view of a semiconductor chip that is an example of a semiconductor integrated circuit device common to the embodiments of the present application.

FIG. 2 is a sectional view of a package showing the shape of laminated semiconductor chips as an example of a semiconductor integrated circuit device common to the embodiments of the present application.

FIG. 3 is a sectional view (corresponding to the section taken on line X-X′ in FIG. 1) of a semiconductor chip that is an example of a semiconductor integrated circuit device according to Embodiment 1 (a whole through electrode top end interface is covered with a film of a kind of silicon nitride in a via middle method) of the present application.

FIG. 4 is a sectional view of a device (at the time of forming a pre-metal wiring layer) showing a process in a method for producing a semiconductor integrated circuit device corresponding to the device structure shown in FIG. 3.

FIG. 5 is a sectional view of a device (at the time of finishing filling a through via) showing a process in a method for producing a semiconductor integrated circuit device corresponding to the device structure shown in FIG. 3.

FIG. 6 is a sectional view of a device (at the time of forming a copper diffusion barrier insulation film at a through electrode top end interface) showing a process in a method for producing a semiconductor integrated circuit device corresponding to the device structure shown in FIG. 3.

FIG. 7 is a sectional view of a device (at the time of forming a first layer embedded wiring layer interlayer insulation film) showing a process in a method for producing a semiconductor integrated circuit device corresponding to the device structure shown in FIG. 3.

FIG. 8 is a sectional view of a device (at the time of forming apertures for first layer embedded wiring) showing a process in a method for producing a semiconductor integrated circuit device corresponding to the device structure shown in FIG. 3.

FIG. 9 is a sectional view of a device (at the time of forming a second layer embedded wiring layer bottom end barrier insulation film) showing a process in a method for producing a semiconductor integrated circuit device corresponding to the device structure shown in FIG. 3.

FIG. 10 is a sectional view of a device (at the time of forming a pad wiring layer) showing a process in a method for producing a semiconductor integrated circuit device corresponding to the device structure shown in FIG. 3.

FIG. 11 is a sectional view (corresponding to the section taken on line X-X′ in FIG. 1) of a semiconductor chip that is an example of a semiconductor integrated circuit device according to Embodiment 2 (only a through via forming region at a through electrode top end interface is covered with a film of a kind of silicon nitride in a via middle method) of the present application.

FIG. 12 is a sectional view of a device (at the time of forming a pre-metal wiring layer) showing a process in a method for producing a semiconductor integrated circuit device corresponding to the device structure shown in FIG. 11.

FIG. 13 is a sectional view of a device (at the time of finishing filling a through via) showing a process in a method for producing a semiconductor integrated circuit device corresponding to the device structure shown in FIG. 11.

FIG. 14 is a sectional view of a device (at the time of forming a copper diffusion barrier insulation film at a through electrode top end interface) showing a process in a method for producing a semiconductor integrated circuit device corresponding to the device structure shown in FIG. 11.

FIG. 15 is a sectional view of a device (at the time of forming a resist film for processing a copper diffusion barrier insulation film at a through electrode top end interface) showing a process in a method for producing a semiconductor integrated circuit device corresponding to the device structure shown in FIG. 11.

FIG. 16 is a sectional view of a device (at the time of processing a copper diffusion barrier insulation film at a through electrode top end interface) showing a process in a method for producing a semiconductor integrated circuit device corresponding to the device structure shown in FIG. 11.

FIG. 17 is a sectional view of a device (at the time of removing a resist film for processing a copper diffusion barrier insulation film at a through electrode top end interface) showing a process in a method for producing a semiconductor integrated circuit device corresponding to the device structure shown in FIG. 11.

FIG. 18 is a sectional view of a device (at the time of forming a first layer embedded wiring layer interlayer insulation film) showing a process in a method for producing a semiconductor integrated circuit device corresponding to the device structure shown in FIG. 11.

FIG. 19 is a sectional view of a device (at the time of forming apertures for first layer embedded wiring) showing a process in a method for producing a semiconductor integrated circuit device corresponding to the device structure shown in FIG. 11.

FIG. 20 is a sectional view of a device (at the time of forming a first layer embedded wiring layer) showing a process in a method for producing a semiconductor integrated circuit device corresponding to the device structure shown in FIG. 11.

FIG. 21 is a sectional view of a device (at the time of forming a second layer embedded wiring layer bottom end barrier insulation film) showing a process in a method for producing a semiconductor integrated circuit device corresponding to the device structure shown in FIG. 11.

FIG. 22 is a sectional view (corresponding to the section taken on line X-X′ in FIG. 1) of a semiconductor chip that is an example of a semiconductor integrated circuit device according to Embodiment 3 (only a through via forming region at a through electrode top end interface is covered with a film of a kind of silicon nitride in a wiring layer middle via method) of the present application.

FIG. 23 is a sectional view of a device (at the time of forming a pre-metal insulation film) showing a process in a method for producing a semiconductor integrated circuit device corresponding to the device structure shown in FIG. 22.

FIG. 24 is a sectional view of a device (at the time of finishing filling a through via) showing a process in a method for producing a semiconductor integrated circuit device corresponding to the device structure shown in FIG. 22.

FIG. 25 is a sectional view of a device (at the time of forming a copper diffusion barrier insulation film at a through electrode top end interface) showing a process in a method for producing a semiconductor integrated circuit device corresponding to the device structure shown in FIG. 22.

FIG. 26 is a sectional view of a device (at the time of forming a resist film for processing a copper diffusion barrier insulation film at a through electrode top end interface) showing a process in a method for producing a semiconductor integrated circuit device corresponding to the device structure shown in FIG. 22.

FIG. 27 is a sectional view of a device (at the time of processing a copper diffusion barrier insulation film at a through electrode top end interface) showing a process in a method for producing a semiconductor integrated circuit device corresponding to the device structure shown in FIG. 22.

FIG. 28 is a sectional view of a device (at the time of removing a resist film for processing a copper diffusion barrier insulation film at a through electrode top end interface) showing a process in a method for producing a semiconductor integrated circuit device corresponding to the device structure shown in FIG. 22.

FIG. 29 is a sectional view of a device (at the time of forming apertures for first layer embedded wiring) showing a process in a method for producing a semiconductor integrated circuit device corresponding to the device structure shown in FIG. 22.

FIG. 30 is a sectional view of a device (at the time of forming a first layer embedded wiring layer) showing a process in a method for producing a semiconductor integrated circuit device corresponding to the device structure shown in FIG. 22.

FIG. 31 is a sectional view of a device (at the time of forming a second layer embedded wiring layer bottom end barrier insulation film) showing a process in a method for producing a semiconductor integrated circuit device corresponding to the device structure shown in FIG. 22.

FIG. 32 is a sectional view of a device (at the time of forming a third layer embedded wiring layer bottom end barrier insulation film) showing a process in a method for producing a semiconductor integrated circuit device corresponding to the device structure shown in FIG. 22.

FIG. 33 is a sectional view of a device (at the time of forming a pad wiring layer) showing a process in a method for producing a semiconductor integrated circuit device corresponding to the device structure shown in FIG. 22.

FIG. 34 is a sectional view (corresponding to the section taken on line X-X′ in FIG. 1) of a semiconductor chip that is an example of a semiconductor integrated circuit device according to Embodiment 4 (a copper diffusion preventive insulation film is not formed at a through electrode top end interface in a via middle method) of the present application.

FIG. 35 is a sectional view (corresponding to the section taken on line X-X′ in FIG. 1) of a semiconductor chip produced by a method for producing a semiconductor integrated circuit device according to Embodiment 5 (a whole through electrode top end interface is covered with a film of a kind of silicon nitride in a via last method) of the present application.

FIG. 36 is a sectional view of a through electrode section (at the time of finishing copper plating) showing Modified Example 1 (a recess part is formed by plating) of a through electrode top end structure and the process thereof common to the embodiments of the present application.

FIG. 37 is a sectional view of a through electrode section (at the time of flattening a surface) showing Modified Example 1 (a recess part is formed by plating) of a through electrode top end structure and the process thereof common to the embodiments of the present application.

FIG. 38 is a sectional view of a through electrode section (at the time of forming a metal diffusion barrier insulation film of a kind of silicon nitride) showing Modified Example 1 (a recess part is formed by plating) of a through electrode top end structure and the process thereof common to the embodiments of the present application.

FIG. 39 is a sectional view of a through electrode section (at the time of flattening a surface) showing Modified Example 2 (a recess part is formed by lithography) of a through electrode top end structure and the process thereof common to the embodiments of the present application.

FIG. 40 is a top view of the periphery of a through electrode section (at the time of forming a resist film for processing a recess part) showing Modified Example 2 (a recess part is formed by lithography) of a through electrode top end structure and the process thereof common to the embodiments of the present application.

FIG. 41 is a sectional view of a through electrode section (at the time of forming a resist film for processing a recess part, corresponding to the section taken on line A-A′ in FIG. 40) showing Modified Example 2 (a recess part is formed by lithography) of a through electrode top end structure and the process thereof common to the embodiments of the present application.

FIG. 42 is a sectional view of a through electrode section (at the time of etching a recess part) showing Modified Example 2 (a recess part is formed by lithography) of a through electrode top end structure and the process thereof common to the embodiments of the present application.

FIG. 43 is a sectional view of a through electrode section (at the time of removing a resist film for processing a recess part) showing Modified Example 2 (a recess part is formed by lithography) of a through electrode top end structure and the process thereof common to the embodiments of the present application.

FIG. 44 is a sectional view of a through electrode section (at the time of forming a metal diffusion barrier insulation film of a kind of silicon nitride) showing Modified Example 2 (a recess part is formed by lithography) of a through electrode top end structure and the process thereof common to the embodiments of the present application.

### DETAILED DESCRIPTION

### Outlines of Embodiments

Firstly, the outlines of representative embodiments of the invention disclosed in the present application are explained.

1. A semiconductor integrated circuit device includes (a) a semiconductor substrate having a first main surface and a second main surface, (b) a semiconductor element forming region and a through via forming region formed on the side of the first main surface, (c) a pre-metal wiring layer formed over the first main surface, (d) three or more embedded wiring layers formed over the pre-metal wiring layer, (e) a pad wiring layer formed over the three or more embedded wiring layers, (f) metal diffusion preventive insulation films formed at a plurality of interfaces over the pre-metal wiring layer and between the embedded wiring layers respectively, and (g) a through electrode being formed in the through via forming region, at least passing through the pre-metal wiring layer, and reaching the second main surface of the semiconductor substrate.

At the plural interfaces, a first insulation film of a kind of silicon nitride is formed as the metal diffusion preventive insulation film at the interface touching the top end of the through electrode, and insulation films of a kind of silicon carbide are formed as the metal diffusion preventive insulation films at the other interfaces respectively.

2. In a semiconductor integrated circuit device according to the item 1, the first insulation film is formed in the semiconductor element forming region and the through via forming region.

3. In a semiconductor integrated circuit device according to the item 1, the first insulation film is formed in the through via forming region.

4. In a semiconductor integrated circuit device according to any one of the items 1 to 3, the interface touching the top end of the through electrode is the interface between the pre-metal wiring layer and the three or more embedded wiring layers.

5. In a semiconductor integrated circuit device according to any one of the items 1 to 3, the interface touching the top end of the through electrode is any one of the interfaces between the three or more embedded wiring layers.

6. In a semiconductor integrated circuit device according to the item 5, a predetermined insulation film of a kind of silicon carbide with which the semiconductor element forming region, the through via forming region, and the first insulation film are covered is formed at the interface touching the top end of the through electrode.

7. In a semiconductor integrated circuit device according to any one of the items 1 to 6, the semiconductor integrated circuit device further includes (h) a second insulation film of a kind of silicon nitride formed at the interface between the three or more embedded wiring layers and the pad wiring layer.

8. In a semiconductor integrated circuit device according to any one of the items 1 to 7, the three or more embedded wiring layers are embedded wiring layers of a kind of copper.

9. In a method for producing a semiconductor integrated circuit device, the semiconductor integrated circuit device includes (a) a semiconductor substrate having a first main surface and a second main surface, (b) a semiconductor element forming region and a through via forming region formed on the side of the first main surface, (c) a pre-metal wiring layer formed over the first main surface, (d) three or more embedded wiring layers formed over the pre-metal wiring layer, (e) a pad wiring layer formed over the three or more embedded wiring layers, (f) metal diffusion preventive insulation films formed at a plurality of interfaces over the pre-metal wiring layer and between the embedded wiring layers respectively, and (g) a through electrode being formed in the through via forming region, at least passing through the pre-metal wiring layer, and reaching the second main surface of the semiconductor substrate. In the method, at the plural interfaces, a first insulation film of a kind of silicon nitride is formed as the metal diffusion preventive insulation film at the interface touching the top end of the through electrode, and insulation films of a kind of silicon carbide are formed as the metal diffusion preventive insulation films at the other interfaces respectively, and an electrode that is to be the through electrode is embedded after the insulation films of the wiring layers below the interface touching the top end of the through electrode are formed and before the wiring layers above the interface touching the top end of the through electrode are formed.

10. In the method for producing a semiconductor integrated circuit device according to the item 9, the first insulation film is formed in the semiconductor element forming region and the through via forming region.

11. In the method for producing a semiconductor integrated circuit device according to the item 9, the first insulation film is formed in the through via forming region.

12. In the method for producing a semiconductor integrated circuit device according to any one of the items 9 to 11, the interface touching the top end of the through electrode is the interface between the pre-metal wiring layer and the lowermost layer in the three or more embedded wiring layers.

13. In the method for producing a semiconductor integrated circuit device according to any one of the items 9 to 11, the interface touching the top end of the through electrode is any one of the interfaces between the three or more embedded wiring layers.

14. In the method for producing a semiconductor integrated circuit device according to the item 13, a predetermined insulation film with which the semiconductor element forming region, the through via forming region, and the first insulation film are covered is formed at the interface touching the top end of the through electrode.

15. In the method for producing a semiconductor integrated circuit device according to any one of the items 9 to 14, the semiconductor integrated circuit device further includes (h) a second insulation film of a kind of silicon nitride formed at the interface between the three or more embedded wiring layers and the pad wiring layer.

16. In the method for producing a semiconductor integrated circuit device according to any one of the items 9 to 15, formation of the through electrode is after the insulation films of the wiring layers below the interface touching the top end of the through electrode are formed and before aperture are formed in the insulation films of the wiring layers.

17. A semiconductor integrated circuit device includes (a) a semiconductor substrate having a first main surface and a second main surface, (b) a semiconductor element forming region and a through via forming region formed on the side of the first main surface, (c) a pre-metal wiring layer formed over the first main surface, (d) three or more embedded wiring layers formed over the pre-metal wiring layer, (e) a pad wiring layer formed over the three or more embedded wiring layers, (f) metal diffusion preventive insulation films of a kind of silicon carbide formed at a plurality of interfaces between the embedded wiring layers respectively, (g) a through electrode being formed in the through via forming region, passing through the pre-metal wiring layer, and reaching the second main surface of the semiconductor substrate, and (h) a wiring pattern belonging to the lowermost layer in the three or more embedded wiring layers with which the top end of the through electrode is covered. Here, a metal diffusion preventive insulation film is not formed at the pre-metal wiring layer.

18. In a method for producing a semiconductor integrated circuit device, the semiconductor integrated circuit device includes (a) a semiconductor substrate having a first main surface and a second main surface, (b) a semiconductor element forming region and a through via forming region formed on the side of the first main surface, (c) a pre-metal wiring layer formed over the first main surface, (d) three or more embedded wiring layers formed over the pre-metal wiring layer, (e) a pad wiring layer formed over the three or more embedded wiring layers, (f) metal diffusion preventive insulation films of a kind of silicon carbide formed at a plurality of interfaces between the embedded wiring layers respectively, (g) a through electrode being formed in the through via forming region, passing through the pre-metal wiring layer, and reaching the second main surface of the semiconductor substrate, and (h) a wiring pattern belonging to the lowermost layer in the three or more embedded wiring layers with which the top end of the through electrode is covered. In the method, a metal diffusion preventive insulation film is not formed at the pre-metal wiring layer, and an electrode that is to be the through electrode is embedded after the wiring layers below the interface touching the top end of the through electrode are formed and before the wiring layers above the interface touching the top end of the through electrode are formed.

19. In a method for producing a semiconductor integrated circuit device, the semiconductor integrated circuit device includes (a) a semiconductor substrate having a first main surface and a second main surface, (b) a semiconductor element forming region and a through via forming region formed on the side of the first main surface, (c) a pre-metal wiring layer formed over the first main surface, (d) three or more embedded wiring layers formed over the pre-metal wiring layer, (e) a pad wiring layer formed over the three or more embedded wiring layers, (f) first metal diffusion preventive insulation films of a kind of silicon carbide formed at a plurality of interfaces between the embedded wiring layers respectively, (g) a through electrode being formed in the through via forming region, passing through the three or more embedded wiring layers and the pre-metal wiring layer, and reaching the second main surface of the semiconductor substrate, and (h) a second metal diffusion preventive insulation film formed at the interface between the three or more embedded wiring layers and the pad wiring layer. In the method, the second metal diffusion preventive insulation film is formed at a film forming temperature in the range of 250° C. to 300° C. by plasma CVD.

20. In a method for producing a semiconductor integrated circuit device, the semiconductor integrated circuit device includes (a) a semiconductor substrate having a first main surface and a second main surface, (b) a semiconductor element forming region and a through via forming region formed on the side of the first main surface, (c) a pre-metal wiring layer formed over the first main surface, (d) three or more embedded wiring layers formed over the pre-metal wiring layer, (e) a pad wiring layer formed over the three or more embedded wiring layers, (f) metal diffusion preventive insulation films of a kind of silicon carbide formed at a plurality of interfaces between the embedded wiring layers respectively, (g) a through electrode being formed in the through via forming region, passing through the pre-metal wiring layer, and reaching the second main surface of the semiconductor substrate, and (h) a recess part formed at un upper surface of the through electrode. In the method, the recess part is formed when the through electrode is embedded by plating.

21. In a method for producing a semiconductor integrated circuit device, the semiconductor integrated circuit device includes (a) a semiconductor substrate having a first main surface and a second main surface, (b) a semiconductor element forming region and a through via forming region formed on the side of the first main surface, (c) a pre-metal wiring layer formed over the first main surface, (d) three or more embedded wiring layers formed over the pre-metal wiring layer, (e) a pad wiring layer formed over the three or more embedded wiring layers, (f) metal diffusion preventive insulation films of a kind of silicon carbide formed at a plurality of interfaces between the embedded wiring layers respectively, (g) a through electrode being formed in the through via forming region, passing through the pre-metal wiring layer, and reaching the second main surface of the semiconductor substrate, and (h) a recess part formed at an upper surface of the through electrode. In the method, the recess part is formed by etching the through electrode while a resist film is used as a mask.

22. In a semiconductor integrated circuit device, the semiconductor integrated circuit device includes (a) a semiconductor substrate having a first main surface and a second main surface, (b) a semiconductor element forming region and a through via forming region formed on the side of the first main surface, (c) a pre-metal wiring layer formed over the first main surface, (d) three or more embedded wiring layers formed over the pre-metal wiring layer, (e) a pad wiring layer formed over the three or more embedded wiring layers, (f) metal diffusion preventive insulation films of a kind of silicon carbide formed at a plurality of interfaces between the embedded wiring layers respectively, (g) a through electrode being formed in the through via forming region, passing through the pre-metal wiring layer, and reaching the second main surface of the semiconductor substrate, and (h) a wiring pattern belonging to the lowermost layer in the three or more embedded wiring layers with which the top end of the through electrode is completely covered. In the method, a plane area of the wiring pattern is larger than a plane area of the through electrode and an upper surface of the through electrode is completely covered with a barrier metal of the wiring pattern.

### [Explanations of Description Forms, Basic Terms, and Usage in the Present Application]

1. In the present application, the descriptions of embodiments are neither independent nor separate from each other and one of the parts of a single case is a detail of another part thereof or a modified case of a part or the whole part thereof unless otherwise particularly specified even though there are some cases where the descriptions are divided into plural sections for convenience sake if necessary. Further, repetitions of similar parts are omitted in principle. Furthermore, constituent components in embodiments are not essential except when it is particularly specified otherwise, when the number is limited theoretically, or when it is obviously otherwise from context.

Moreover, in the present application, when the term “a semiconductor device” or “a semiconductor integrated circuit device” is cited, the term mostly means a device formed by integrating various transistor single bodies (active elements) and resistances, capacitors, and others around them over a semiconductor chip (for example, a monocrystal silicon substrate) or the like. Here, a representative example of such various transistors can be a MISFET (Metal Insulator Semiconductor Field Effect Transistor) represented by a MOSFET (Metal Oxide Semiconductor Field Effect Transistor). In this case, a representative example of an integrated circuit structure can be a CMIS (Complementary Metal Insulator Semiconductor) type integrated circuit represented by a CMOS (Complementary Metal Oxide Semiconductor) type integrated circuit formed by combining an N-channel MISFET with a P-channel MISFET.

A today's wafer process of a semiconductor integrated circuit device, namely an LSI (Large Scale Integration), is generally divided broadly into: an FEOL (Front End of Line) process ranging from carry-in of a silicon wafer as a primary material to the vicinity of a pre-metal process (a process including the processes of forming an interlayer insulation film between the bottom end of an M1 wiring layer and a gate electrode structure and the like, forming a contact hole, tungsten plugging, embedding, and others); and a BEOL (Back End of Line) process beginning from the process of forming the M1 wiring layer and reaching the vicinity of the process of forming a pad aperture in a final passivation film over a pad electrode of a kind of aluminum (in a wafer level package process, the process is included). In the FEOL process, a gate electrode patterning process, a contact hole forming process, and the like are microfabrication processes requiring particularly fine processing. Meanwhile, in the BEOL process, microfabrication is particularly required at a via and trench forming process, in particular at a comparatively lower layer local wiring (for example, a fine embedded wiring ranging roughly from M1 to M3 in the case of embedded wiring of about four-layered structure and roughly from M1 to M5 in the case of embedded wiring of about ten-layered structure) or the like. Here, the term “MN (usually N=1 to about 15)” represents the wiring of N-th from the bottom. M1 represents a first layer wiring and M3 represents a third layer wiring.

2. In the descriptions of embodiments and others on materials and compositions likewise, even in the case of the description of “X including A” or the like, it does not exclude the case where a component other than A is included as one of the main constituent components except when it is particularly specified otherwise or when it is obviously otherwise from context. For example, with regard to a component, the description means “X including A as a main component” or the like. Further for example, it goes without saying that the description of “a silicon member” or the like: does not mean that the silicon member is limited to pure silicon; but means that the silicon member includes a member including an SiGe alloy, another multiple alloy containing silicon as a main component, another additive, and the like. Furthermore, the descriptions of “copper”, “a copper member”, and the like do not indicate only comparatively pure copper and are regarded as a metal member containing copper as a main component is meant.

Likewise, it goes without saying that the descriptions of “a silicon oxide film”, “a insulation film of a kind of silicon oxide”, and the like include not only a comparatively pure undoped silicon dioxide but also a thermally-oxidized film such as FSG (Fluorosilicate Glass), TEOS-based silicon oxide, SiOC (Silicon Oxicarbide), carbon-doped silicon oxide, OSG (Organosilicate Glass), PSG (Phosphorus Silicate Glass), or BPSG (Borophosphosilicate Glass), a CVD oxide film, coating type silicon oxide such as SOG (Spin On Glass) and nano-clustering silica (NCS), a Low-k insulation film of a kind of silica formed by introducing pores to a member similar to the above members (a porous type insulation film), and another insulation film of a kind of silicon containing an above member as a main constituent component.

A Low-k interlayer insulation film material frequently used in a BEOL process of an integrated circuit is typically SiOC and, when the term “SiOC” is simply cited in the present application, it means nonporous SiOC. In contrast, when porous SiOC that is a so-called ELK (Extreme Low-k) film is indicated, the term “a porous SiOC film” and the like are used.

Further, as a insulation film of a kind of silicon generally used in the semiconductor field along with a insulation film of a kind of silicon oxide, a insulation film of a kind of silicon nitride/silicon carbide is used. As materials belonging to the kind, there are SiN, SiC, SiCN, SiNH, SiCNH, SiCO, and others. Here, when the term “silicon nitride” is cited, the term includes both SiN and SiNH unless otherwise particularly specified. Likewise, when the term “SiCN” is cited, the term includes both SiCN and SiCNH unless otherwise particularly specified.

Here, SiC has a nature similar to SiN but SiON (it is generally believed that the content of a former element is larger than that of a latter element in the order of description) should be classified rather as a insulation film of a kind of silicon oxide in many cases.

In the present application, when the term “a insulation film of a kind of silicon nitride” is cited with regard to a copper diffusion barrier film, the term mostly means SiN and SiNH. Further likewise, when the term “a insulation film of a kind of silicon carbide” is cited, the term mostly means SiC, SiCN, SiCO, SiCNH, and the like.

3. Likewise, appropriate examples are shown with regard to drawings, positions, attributes, and the like but it goes without saying that they are not strictly limited to the examples except when it is particularly specified otherwise or when it is obviously otherwise from context.

4. Further, when a specific numerical value or quantity is cited, it may be a numerical value exceeding the specific value or may be a numerical value lower than the specific value except when it is particularly specified otherwise, when the number is limited theoretically, or when it is obviously otherwise from context.

5. When the term “a wafer” is cited, generally the term means a monocrystal silicon wafer over which a semiconductor integrated circuit device (a semiconductor device and an electronic device are included) is formed but it goes without saying that a composite wafer or the like including an insulation substrate such as an epitaxial wafer, an SOI substrate, or an LCD glass substrate and a semiconductor layer or the like is included.

### Details of Embodiments

Embodiments are described further in detail. In the drawings, identical or similar parts are represented with identical or similar symbols or reference numerals and explanations are not repeated in principle.

Further, in attached drawings, hatching or the like for representing a cross section is sometimes omitted when it rather complicates the situation or when it can be obviously distinguished from a vacancy. In this regard, when it is obvious from explanations or the like, the profile line of the background may sometimes be omitted even in the case of a planarly closed hole. In contrast, even when a part is not a cross section, hatching may be applied sometimes in order to demonstrate that the part is not a vacancy.

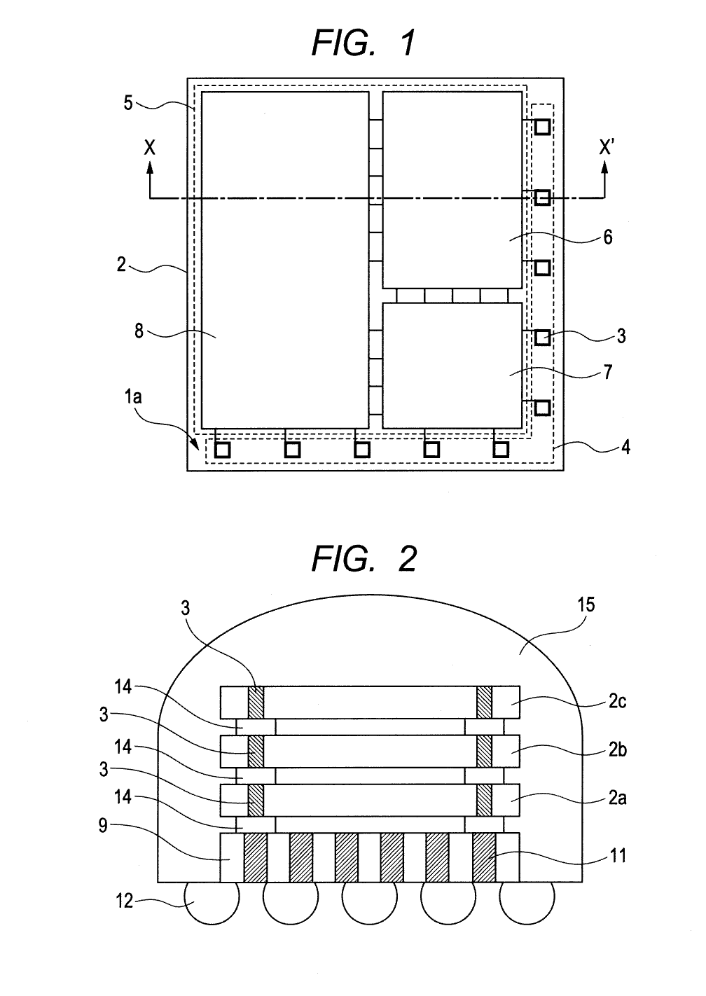

1. Explanations of a semiconductor chip that is an example of a semiconductor integrated circuit device common to the embodiments of the present application and the laminated structure thereof (mostly FIGS. 1 and 2). In this section, the outlines of an example of the planar layout of a semiconductor chip formed by applying a device structure and a production method thereof in the following embodiments and the cross-sectional structure of a lamination type semiconductor integrated circuit device (stacked package) formed by stacking those are explained.

FIG. 1 is an overall top view of a semiconductor chip that is an example of a semiconductor integrated circuit device common to the embodiments of the present application. FIG. 2 is a sectional view of a package showing the shape of laminated semiconductor chips as an example of a semiconductor integrated circuit device common to the embodiments of the present application. On the basis of those figures, a semiconductor chip that is an example of a semiconductor integrated circuit device common to the embodiments of the present application and the laminated structure thereof are explained.

As shown in FIG. 1, a semiconductor element forming region 5 having a logic circuit block 6, an analog circuit block 7, a memory circuit block 8, and the like and a through via forming region 4 having a plurality of through electrode sections 3 are formed over a device main surface 1a (the surface on the other side of a rear surface 1b) of a semiconductor chip 2.

Successively, a stacked package formed by stacking various semiconductor chips 2a, 2b, and 2c having layouts similar to the layout (namely, the through via forming region 4 and the semiconductor element forming region 5) of the semiconductor chip 2 shown in FIG. 1 is shown in FIG. 2. As shown in FIG. 2, for example a plurality of chips 2a, 2b, and 2c having through electrode sections 3 are stacked over a wiring substrate 9 having through electrodes 11 while inter-substrate interconnections 14 (for example, a junction structure of copper-electrode/copper-tin-joint/copper-electrode) are interposed in between. Such a laminated body is sealed with a sealing resin 15 or the like as necessary and solder bump electrodes 12 or the like are formed at the bottom end of the seal or the like as necessary.

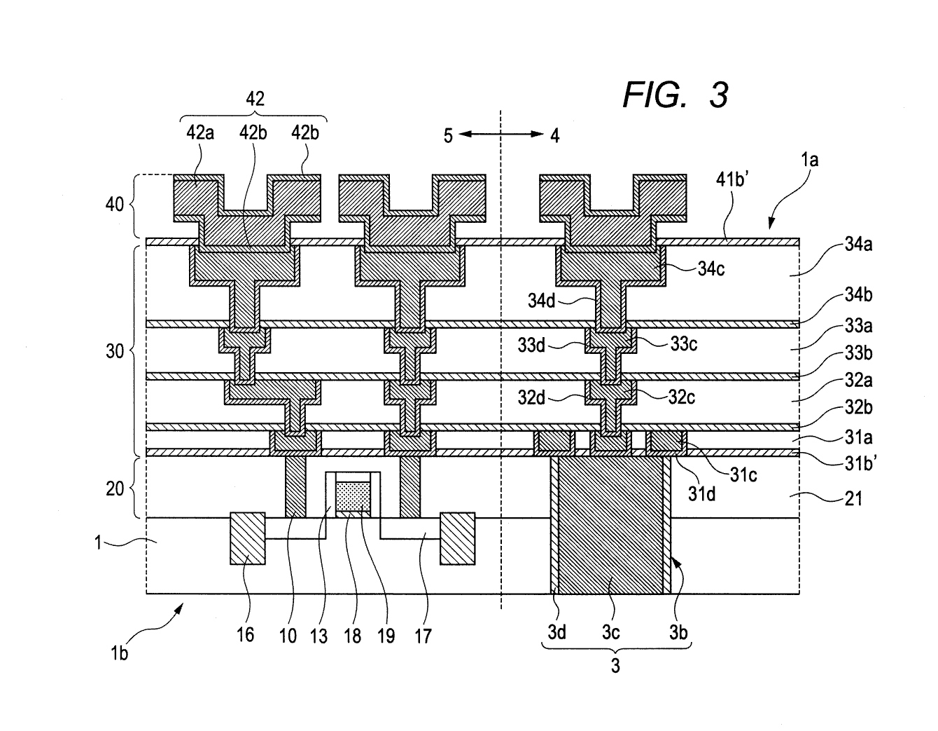

2. Explanations of the cross-sectional structure of a semiconductor chip that is an example of a semiconductor integrated circuit device according to Embodiment 1 (a whole through electrode top end interface is covered with a film of a kind of silicon nitride in a via middle method) of the present application (mainly FIG. 3). Examples of a copper diffusion barrier insulation film used for a wiring layer are a film of a kind of silicon nitride represented by an SiN film or the like and a film of a kind of silicon carbide represented by an SiC film or the like. The film of a kind of silicon nitride is excellent in copper diffusion preventive performance and film stability but the disadvantage thereof is that the electric permittivity is relatively high. In contrast, the film of a kind of silicon carbide has the advantage that the electric permittivity is relatively low although it is inferior in film stability. Among the films of a kind of silicon carbide, an SiCN or SiCNH film is comparable to a film of a kind of silicon nitride in copper diffusion preventive function but inferior in film stability. An SiC or SiCO film is inferior to a film of a kind of silicon nitride in copper diffusion preventive function and film stability but has an electric permittivity relatively lower than an SiCN or SiCNH film. In the present example therefore, it is attempted to increase the speed of operation by using: a copper diffusion preventive insulation film of a kind of silicon nitride (a barrier insulation film) at an interface such as an interlayer insulation film touching the top end of a through electrode that is likely to cause problems of reliability or the like; and a copper diffusion preventive insulation film of a kind of silicon carbide (a barrier insulation film) at an interface such as another interlayer insulation film. Here, at an interface between the uppermost embedded wiring layer and a pad wiring layer, a copper diffusion preventive insulation film of a kind of silicon nitride (in such an upper layer wiring, the magnitude of an electric permittivity scarcely affects device operation) is most appropriate for use from the viewpoint of film quality and processing of the upper layer film (for example, an etching selectivity at the time of forming a tungsten plug or the like between the uppermost embedded wiring and a pad of a kind of aluminum) or the like but it goes without saying that a copper diffusion preventive insulation film of a kind of silicon carbide can also be used.

Although the total number of embedded wirings is set at 4 in order to secure the brevity of explanations in the present application, wirings of about 3 to 15 in total number are widely used in an ordinary device. In the case of a thirteen-layered configuration for example, an example of the configuration is the combination of seven local wiring layers, four intermediate wiring layers, and two global wiring layers.

FIG. 3 is a sectional view (corresponding to the section taken on line X-X′ in FIG. 1) of a semiconductor chip that is an example of a semiconductor integrated circuit device according to Embodiment 1 (a whole through electrode top end interface is covered with a film of a kind of silicon nitride in a via middle method) of the present application. On the basis of the figure, the cross-sectional structure of a semiconductor chip that is an example of a semiconductor integrated circuit device according to Embodiment 1 (a whole through electrode top end interface is covered with a film of a kind of silicon nitride in a via middle method) of the present application is explained.

As shown in FIG. 3, for example: an STI (Shallow Trench Isolation) region 16 and a source/drain region 17 configuring an MISFET are formed in the surface region (mainly a semiconductor element forming region 5) on the side of the device main surface 1a of a P-type monocrystal silicon substrate 1 (the semiconductor chip 2 in FIG. 1); and a gate insulation film 18 (including a composite film including a High-k film and the like) configuring the gate stack structure of the MISFET, a gate electrode 19 (including a composite film such as a polysilicon layer and a metal layer), a sidewall insulation film 13, a gate cap insulation film, and the like are formed over the surface region.

Further, a pre-metal insulation film 21 (the part corresponds to a pre-metal wiring layer 20) having a insulation film of a kind of silicon oxide (for example, an ordinary SiOC film, namely a nonporous SiOC film) as the main constituent component is formed over the surface region on the side of the device main surface 1a of the semiconductor substrate 1 so as to cover the gate stack structure, and tungsten plugs 10 passing through the pre-metal insulation film 21 are formed in the pre-metal insulation film 21. Meanwhile, in a through via forming region 4, a through electrode section 3 passing through the pre-metal insulation film 21 and the semiconductor substrate 1 is formed and the through electrode section 3 includes a through via 3b (a through hole), a through via inner face insulation film 3d (for example, a insulation film of a kind of silicon oxide, a insulation film of a kind of silicon nitride, or a composite film thereof) formed on the inner face thereof, a through electrode or a through electrode member 3c (usually includes an ambient barrier metal layer and a core metal section of copper, tungsten, or the like, here explanations are made mainly on the basis of a through electrode member of a kind of copper) embedded into the interior of the through via 3b, and the like.

A first layer embedded wiring layer bottom end barrier insulation film 31b′ (a kind of silicon nitride) about 50 nm in thickness for example is formed over the upper face of the pre-metal insulation film 21 and the upper face of the through electrode section 3 and a first layer embedded wiring layer interlayer insulation film 31a (for example, a film of a kind of silicon oxide, namely a porous SiOC film, about 100 nm in thickness) is formed over the first layer embedded wiring layer bottom end barrier insulation film 31b′. A first layer embedded wiring (a single damascene wiring) including a first layer embedded wiring layer wiring metal film 31c, a first layer embedded wiring layer barrier metal film 31d, and the like is embedded into the first layer embedded wiring layer interlayer insulation film 31a. The first layer embedded wiring can be regarded as a local wiring. Here, in the case where the first layer embedded wiring is particularly finer than the other wiring layers or the like, it is also effective to use a laminated nonporous Low-k film including a comparatively thin silicon oxide film of an inorganic kind, a comparatively thick nonporous SiOC film, a comparatively thin silicon oxide film of an inorganic kind, and the like in this order from the bottom as the first layer embedded wiring layer interlayer insulation film 31a.

A second layer embedded wiring layer bottom end barrier insulation film 32b (a kind of silicon carbide) about 50 nm in thickness for example is formed over the first layer embedded wiring layer interlayer insulation film 31a and a second layer embedded wiring layer interlayer insulation film 32a (for example, a film of a kind of silicon oxide, namely a porous SiOC film, about 170 nm in thickness) is formed over the second layer embedded wiring layer bottom end barrier insulation film 32b. A second layer embedded wiring (a dual damascene wiring) including a second layer embedded wiring layer wiring metal film 32c, a second layer embedded wiring layer barrier metal film 32d, and the like is embedded into the second layer embedded wiring layer interlayer insulation film 32a. The second layer embedded wiring can be regarded as a local wiring or an intermediate layer wiring.

Likewise, a third layer embedded wiring layer bottom end barrier insulation film 33b (a kind of silicon carbide) about 50 nm in thickness for example is formed over the second layer embedded wiring layer interlayer insulation film 32a and a third layer embedded wiring layer interlayer insulation film 33a (for example, a film of a kind of silicon oxide, namely a nonporous SiOC film, about 200 nm in thickness) is formed over the third layer embedded wiring layer bottom end barrier insulation film 33b. A third layer embedded wiring (a dual damascene wiring) including a third layer embedded wiring layer wiring metal film 33c, a third layer embedded wiring layer barrier metal film 33d, and the like is embedded into the third layer embedded wiring layer interlayer insulation film 33a. The third layer embedded wiring can be regarded as an intermediate layer wiring.

Moreover, a fourth layer embedded wiring layer bottom end barrier insulation film 34b (a kind of silicon carbide) about 50 nm in thickness for example is formed over the third layer embedded wiring layer interlayer insulation film 33a and a fourth layer embedded wiring layer interlayer insulation film 34a (for example, a film of a kind of silicon oxide, namely a TEOS film, about 800 nm in thickness) is formed over the fourth layer embedded wiring layer bottom end barrier insulation film 34b. A fourth layer embedded wiring (a dual damascene wiring) including a fourth layer embedded wiring layer wiring metal film 34c, a fourth layer embedded wiring layer barrier metal film 34d, and the like is embedded into the fourth layer embedded wiring layer interlayer insulation film 34a. The fourth layer embedded wiring can be regarded as a global wiring.

The part ranging from the first layer embedded wiring layer bottom end barrier insulation film 31b′ to the fourth layer embedded wiring layer interlayer insulation film 34a corresponds to a multilayered embedded wiring layer 30 (three-or-more-layered embedded wiring).

A pad wiring layer bottom end barrier insulation film (a kind of silicon nitride) about 150 nm in thickness for example is formed over the fourth layer embedded wiring layer interlayer insulation film 34a and a pad wiring layer 40 is formed thereover while usually a pad lower via layer (generally a not Low-k but ordinary insulation film of a kind of silicon oxide) into which a tungsten plug or the like is embedded is interposed in between. A pad electrode 42 is formed in the pad wiring layer 40 and the pad electrode 42 includes a pad electrode main metal film 42a in the middle, pad electrode barrier metal films 42b (the upper barrier metal film may be removed at a pad aperture part) above and below the pad electrode main metal film 42a, and the like for example.

Further, generally the upper parts of the pad lower via layer and the pad electrode 42 are covered for example with a final passivation film including an insulation film of a kind of silicon oxide (generally a not Low-k but ordinary insulation film of a kind of silicon oxide) as the lower layer, a insulation film of a kind of silicon nitride as the upper layer, and further if necessary a coating film of an organic kind such as a resin film of a kind of polymide, and the like. Then pad apertures are formed in the final passivation film in accordance with the center parts of the pads 42 respectively.

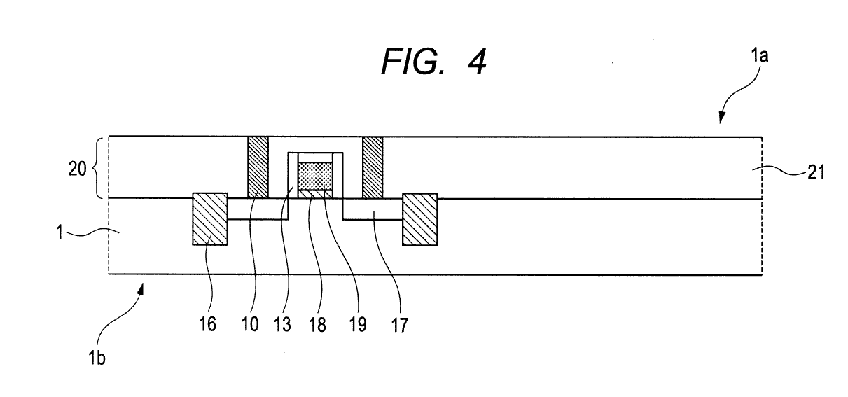

3. Explanations of a process in a method for producing a semiconductor integrated circuit device corresponding to the device structure according to Embodiment 1 (a whole through electrode top end interface is covered with a film of a kind of silicon nitride in a via middle method) of the present application (mainly FIGS. 4 to 10). In this section, the outline of an example of the production process of the device structure explained in the section 2 is explained.

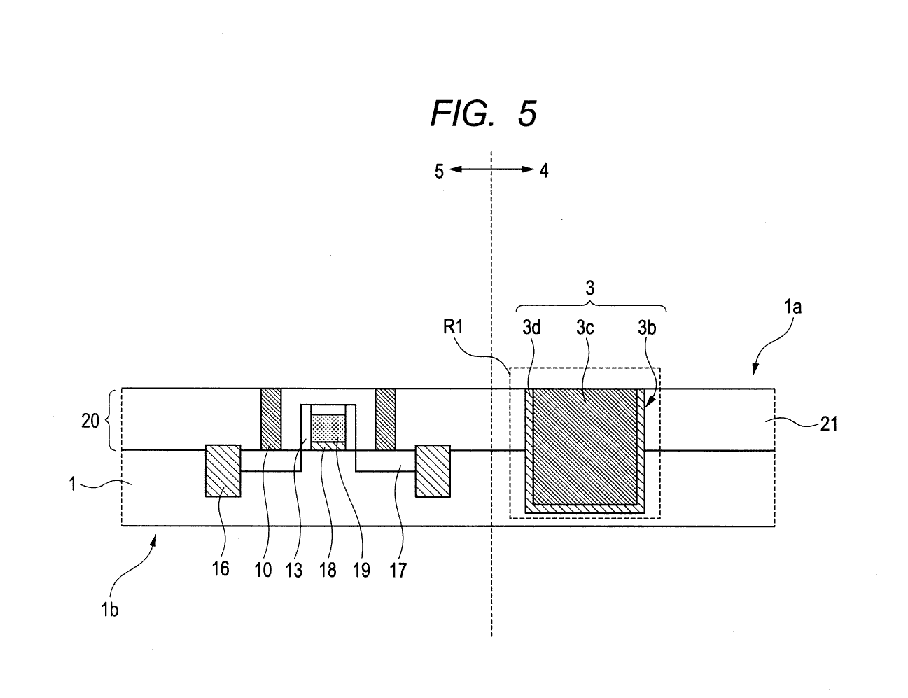

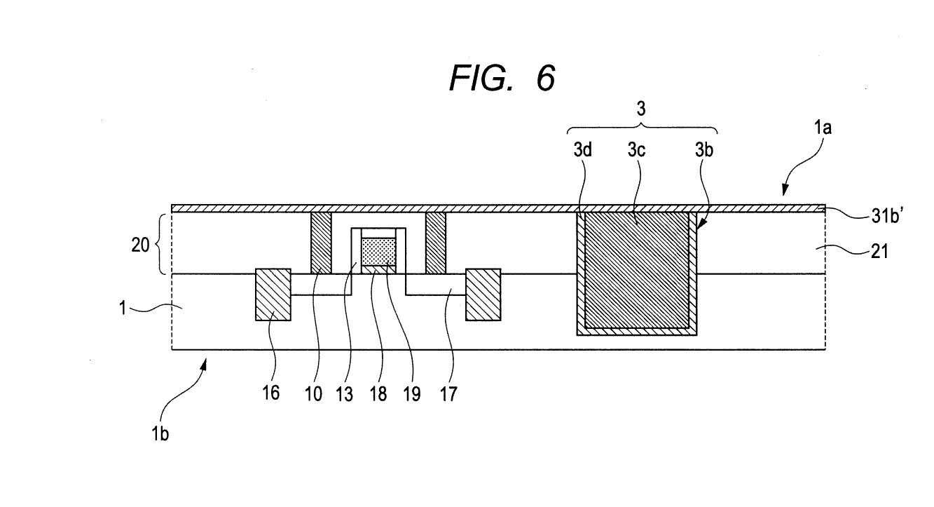

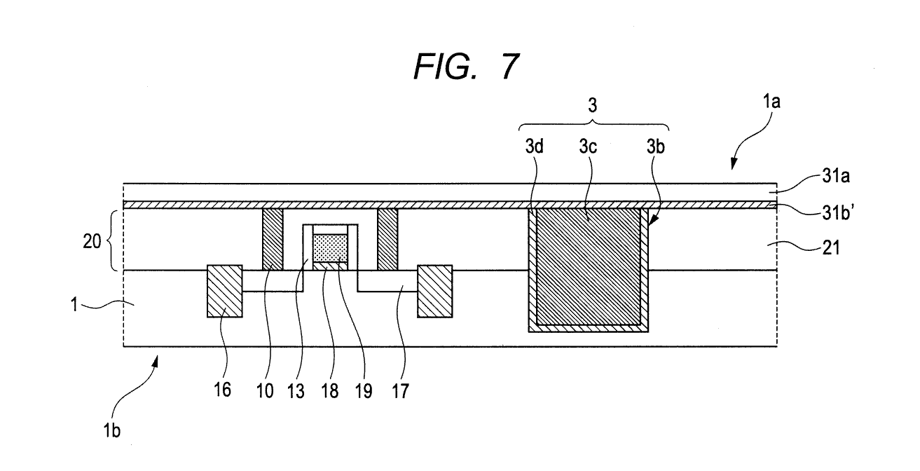

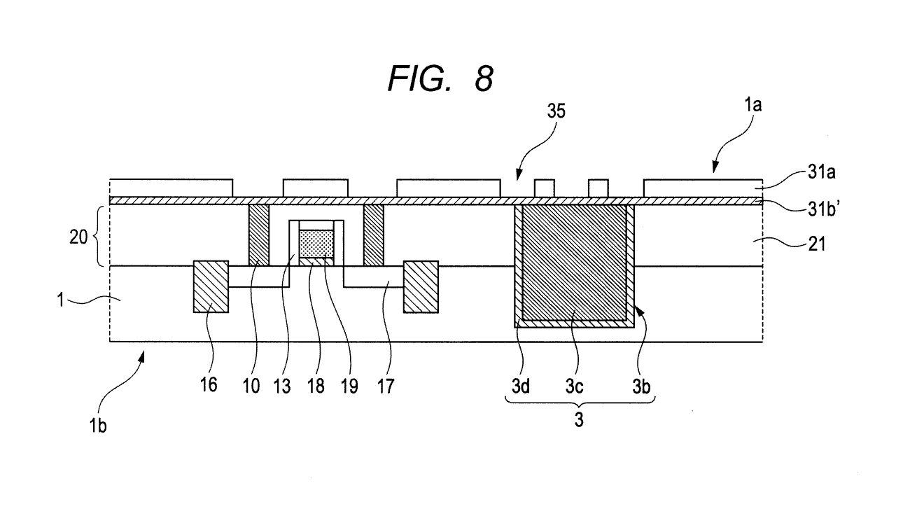

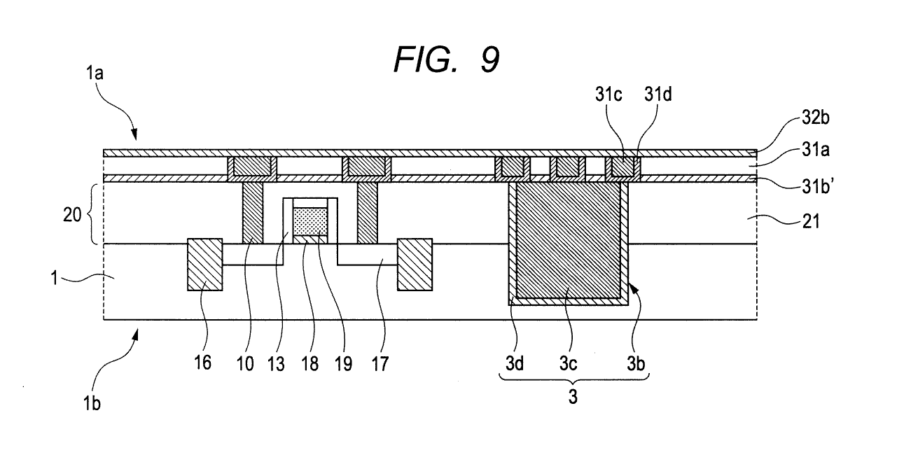

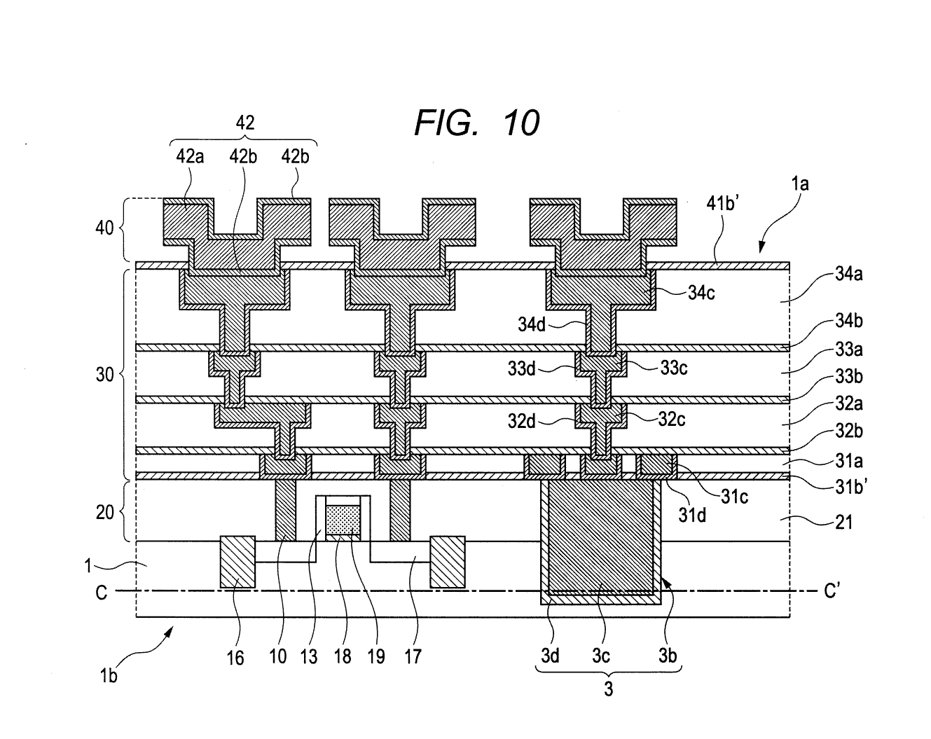

FIG. 4 is a sectional view of a device (at the time of forming a pre-metal wiring layer) showing a process in a method for producing a semiconductor integrated circuit device corresponding to the device structure shown in FIG. 3. FIG. 5 is a sectional view of a device (at the time of finishing filling a through via) showing a process in a method for producing a semiconductor integrated circuit device corresponding to the device structure shown in FIG. 3. FIG. 6 is a sectional view of a device (at the time of forming a copper diffusion barrier insulation film at a through electrode top end interface) showing a process in a method for producing a semiconductor integrated circuit device corresponding to the device structure shown in FIG. 3. FIG. 7 is a sectional view of a device (at the time of forming a first layer embedded wiring layer interlayer insulation film) showing a process in a method for producing a semiconductor integrated circuit device corresponding to the device structure shown in FIG. 3. FIG. 8 is a sectional view of a device (at the time of forming apertures for first layer embedded wiring) showing a process in a method for producing a semiconductor integrated circuit device corresponding to the device structure shown in FIG. 3. FIG. 9 is a sectional view of a device (at the time of forming a second layer embedded wiring layer bottom end barrier insulation film) showing a process in a method for producing a semiconductor integrated circuit device corresponding to the device structure shown in FIG. 3. FIG. 10 is a sectional view of a device (at the time of forming a pad wiring layer) showing a process in a method for producing a semiconductor integrated circuit device corresponding to the device structure shown in FIG. 3. On the basis of those figures, a process in a method for producing a semiconductor integrated circuit device corresponding to the device structure according to Embodiment 1 (a whole through electrode top end interface is covered with a film of a kind of silicon nitride in a via middle method) of the present application is explained.

Firstly, as shown in FIG. 4, after a MISFET is formed over the device main surface 1a of a wafer 1 (here, explanations are made on the basis of a 300φ wafer of p-type monocrystal silicon but the wafer diameter may be 200φ, 450φ, or another, further the wafer is not limited to a monocrystal wafer and may be an epitaxial wafer or an SOI wafer, and furthermore the conduction type may be n-type if necessary), a pre-metal insulation film 21 (an insulation film including an insulation film of a kind of silicon oxide as the main constituent component) about 200 nm in thickness for example is formed over the device main surface 1a of the wafer 1 by CVD (Chemical Vapor Deposition). Successively, anisotropic dry etching is applied to the side of the device main surface 1a of the wafer 1 in a gas atmosphere containing fluorocarbon for example and contact holes are formed. Successively, a barrier metal and a tungsten member are deposited in sequence over the pre-metal insulation film 21 and in the contact holes. Successively, the barrier metal and the tungsten member outside the contact holes are removed and the surface is flattened by metal CMP treatment.

Successively, as shown in FIG. 5, a section 3 that is to be a through electrode section (refer to a through electrode section periphery cut-out region R1) is formed in a through via forming region 4. As the procedure for example, a non-through hole 3b (a non-through hole to be a through via, the depth is about 100 micrometers for example and the planar shape is about 40 micrometers square for example) ranging from the upper face of the pre-metal insulation film 21 to the middle of the semiconductor substrate 1 is formed by dry etching such as a Bosch process (for example, alternately repeating isotropic etching by SF₆ or the like and anisotropic etching by C₄F₈ or the like). Successively, an insulation film (a non-through via inner face insulation film 3d to be a through via inner face insulation film) such as a silicon oxide film is deposited over the upper face of the pre-metal insulation film 21 and the inner face and the bottom face of the non-through hole 3b by CVD or the like. Further, a barrier metal film is deposited thereover by CVD, sputtering, or the like and thereafter a copper seed layer and the like are deposited by CVD, sputtering, or the like. Successively, the non-through hole 3b to be a through via is filled with a copper member by electrolytic plating. Here, a non-through electrode 3c to be a through electrode includes the barrier metal film, the copper seed layer, the plated copper member, and the like. Finally, unnecessary members such as the insulation film 3d and the non-through electrode 3c outside the non-through hole 3b are removed by flattening treatment such as CMP (Chemical Mechanical Polishing).

Successively, as shown in FIG. 6, a copper diffusion preventive insulation barrier film 31b′, namely a silicon nitride film, is formed over nearly the whole upper face of the pre-metal insulation film 21 by plasma CVD or the like. Preferable examples of the film forming conditions of the silicon nitride film are as follows, furnace body used: sheet parallel plate type, gas flow rate: SiH₄ from 10 to 100 sccm (for example, about 30 sccm), NH₃ from 10 to 500 sccm (for example, about 150 sccm), and N₂ from 1,000 to 30,000 sccm (for example, about 3,000 sccm), treatment atmospheric pressure: from 133 to 13,332 Pa (for example, about 1,500 Pa), wafer temperature: from 200° C. to 300° C. (desirably from 250° C. to 300° C. and specifically about 280° C. for example), high-frequency wave power: from 10 to 500 watts at 13.56 MHz (for example, about 100 watts), and film thickness: from 10 to 1,000 nm (for example, about 50 nm). Here, the film forming temperature can be set at about 400° C. as it is generally adopted. By adopting a lower film forming temperature as stated earlier however, it is possible to prevent a copper diffusion preventive film from cracking due to the thermal deformation of a copper member. Such low temperature film forming is effective particularly in the example of the section 9.

Successively, as shown in FIG. 7, a porous SiOC film 31a for example is formed over the silicon nitride film 31b′ by plasma CVD. Successively, as shown in FIG. 8, first layer embedded wiring apertures 35 are formed by lithography. Successively, as shown in FIG. 9, a first layer embedded wiring including a first layer embedded wiring layer wiring metal film 31c (for example, copper), a first layer embedded wiring layer barrier metal film 31d (for example, TaN/Ta, Ru, or the like from the bottom layer), and the like is embedded by a single damascene method. Successively, an SiCN film 32b for example is formed as a second layer embedded wiring layer bottom end barrier insulation film (a kind of silicon carbide) over the porous SiOC film 31a by plasma CVD. As the copper diffusion barrier insulation film of a kind of silicon carbide, besides an SiCN film, an SiCO film, an SIC film, or a composite film thereof can be used (the same is applied hereunder).

Successively, as shown in FIG. 10, a porous SiOC film 32a for example is formed over the SiCN film 32b by plasma CVD. Successively, almost in the same way as above, a second layer embedded wiring including a second layer embedded wiring layer wiring metal film 32c (for example, copper), a second layer embedded wiring layer barrier metal film 32d (for example, TaN/Ta, Ru, or the like from the bottom layer), and the like is embedded by a dual damascene method. Successively, an SiCN film 33b for example is formed as a third layer embedded wiring layer bottom end barrier insulation film (a kind of silicon carbide) over the porous SiOC film 32a by plasma CVD.

Further likewise, a nonporous SiOC film 33a for example is formed over the SiCN film 33b by plasma CVD. Successively, almost in the same way as above, a third layer embedded wiring including a third layer embedded wiring layer wiring metal film 33c (for example, copper), a third layer embedded wiring layer barrier metal film 33d (for example, TaN/Ta, Ru, or the like from the bottom layer), and the like is embedded by a dual damascene method. Successively, an SiCN film 34b for example is formed as a fourth layer embedded wiring layer bottom end barrier insulation film (a kind of silicon carbide) over the nonporous SiOC film 33a by plasma CVD.

Then likewise, a TEOS silicon oxide film 34a for example is formed over the SiCN film 34b by plasma CVD. Successively, almost in the same way as above, a fourth layer embedded wiring including a fourth layer embedded wiring layer wiring metal film 34c (for example, copper), a fourth layer embedded wiring layer barrier metal film 34d (for example, TaN/Ta, Ru, or the like from the bottom layer), and the like is embedded by a dual damascene method. Successively, a silicon nitride film 41b′ for example is formed as a pad wiring layer bottom end barrier insulation film (a kind of silicon nitride) over the TEOS silicon oxide film 34a by plasma CVD.

A pad wiring layer 40 is formed thereafter. Further, a device structure shown in FIG. 3 is obtained by removing the part ranging from the rear surface 1b of the wafer 1 to the surface shown with the line C-C′ in FIG. 10 by back grinding and CMP treatment.

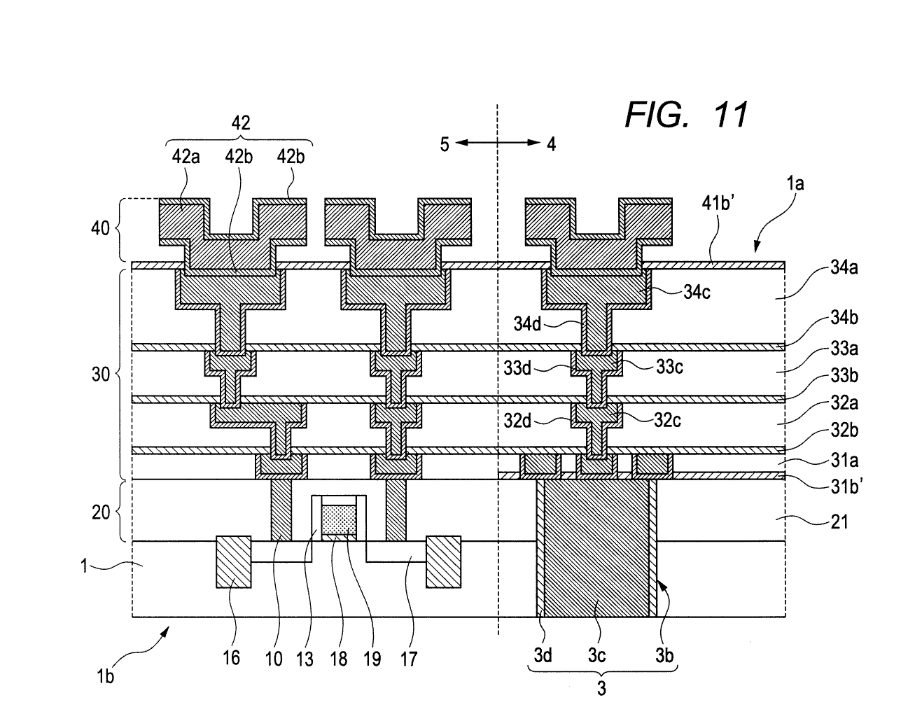

4. Explanations of the cross-sectional structure of a semiconductor chip that is an example of a semiconductor integrated circuit device according to Embodiment 2 (only a through via forming region at a through electrode top end interface is covered with a film of a kind of silicon nitride in a via middle method) of the present application (mainly FIG. 11). A feature of the example explained in this section is, in comparison with the example explained in the section 2, that a copper diffusion preventive barrier insulation film 31b′ at the interface between a pre-metal insulation film 21 and a first layer embedded wiring layer interlayer insulation film 31a is formed only in the through via forming region 4. By so doing, it is possible to exclude a silicon nitride film of a high electric permittivity from a semiconductor element forming region 5 intrinsically scarcely requiring a metal diffusion barrier insulation film and hence it is possible to attempt to increase the speed of circuit operation.

FIG. 11 is a sectional view (corresponding to the cross section taken on line X-X′ in FIG. 1) of a semiconductor chip that is an example of a semiconductor integrated circuit device according to Embodiment 2 (only a through via forming region at a through electrode top end interface is covered with a film of a kind of silicon nitride in a via middle method) of the present application. On the basis of the figure, the cross-sectional structure of a semiconductor chip that is an example of a semiconductor integrated circuit device according to Embodiment 2 (only a through via forming region at a through electrode top end interface is covered with a film of a kind of silicon nitride in a via middle method) of the present application is explained.

As shown in FIG. 11, a silicon nitride film 31b′ (a first layer embedded wiring layer bottom end barrier insulation film of a kind of silicon nitride) is formed only in a through via forming region 4.

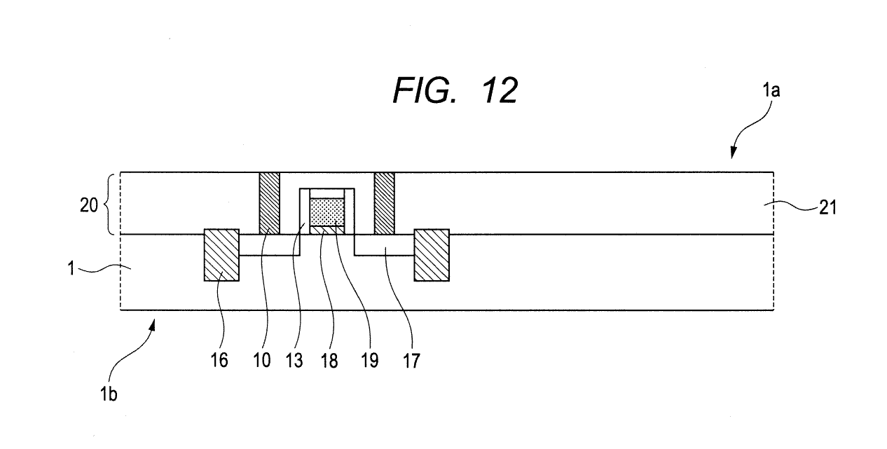

5. Explanations of a process in a method for producing a semiconductor integrated circuit device corresponding to the device structure according to Embodiment 2 (only a through via forming region at a through electrode top end interface is covered with a film of a kind of silicon nitride in a via middle method) of the present application (mainly FIGS. 12 to 21). The difference between the process of this section and the process explained in the section 3: is based on the difference between the device structure of the section 4 and the device structure of the section 2; and is that the process of this section includes a process of patterning a first layer embedded wiring layer bottom end barrier insulation film of a kind of silicon nitride 31b′ in FIG. 11.

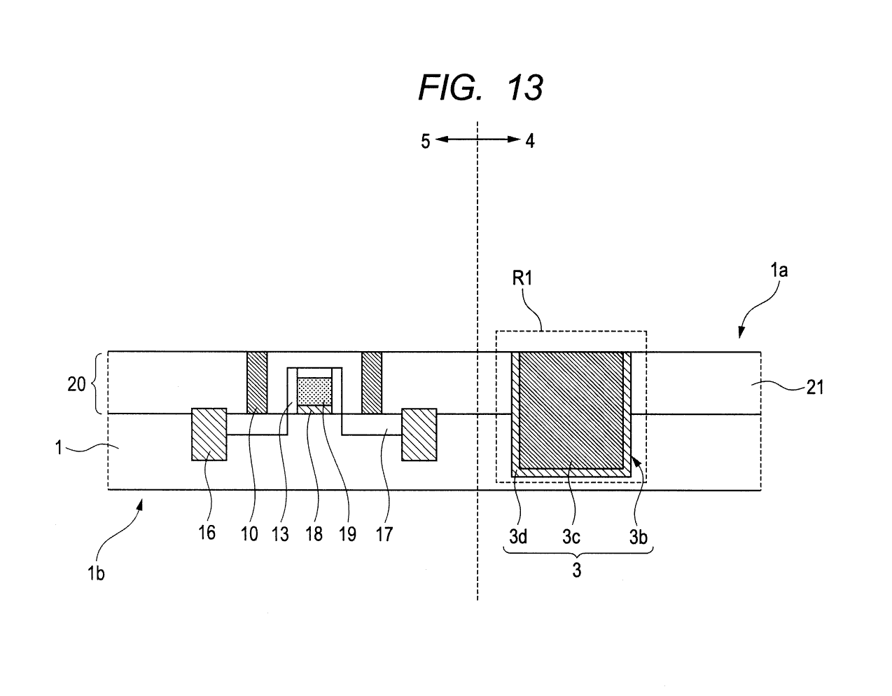

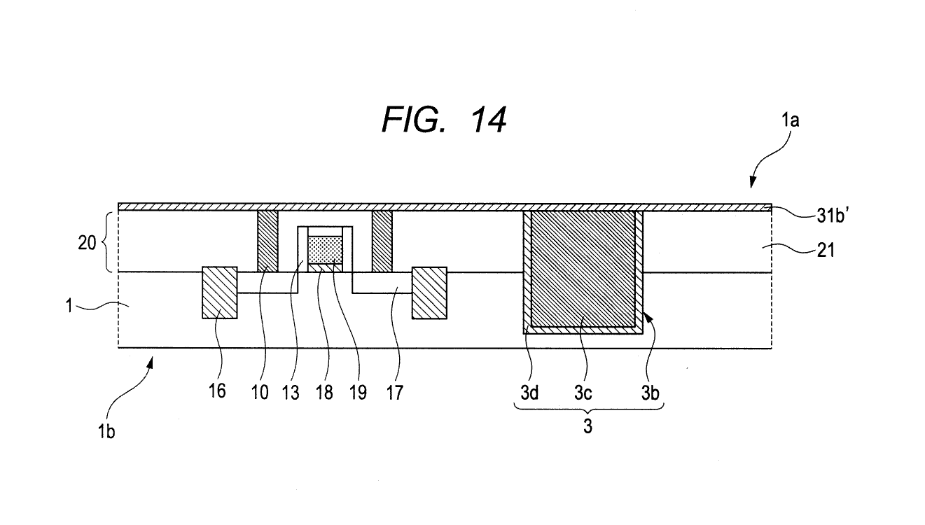

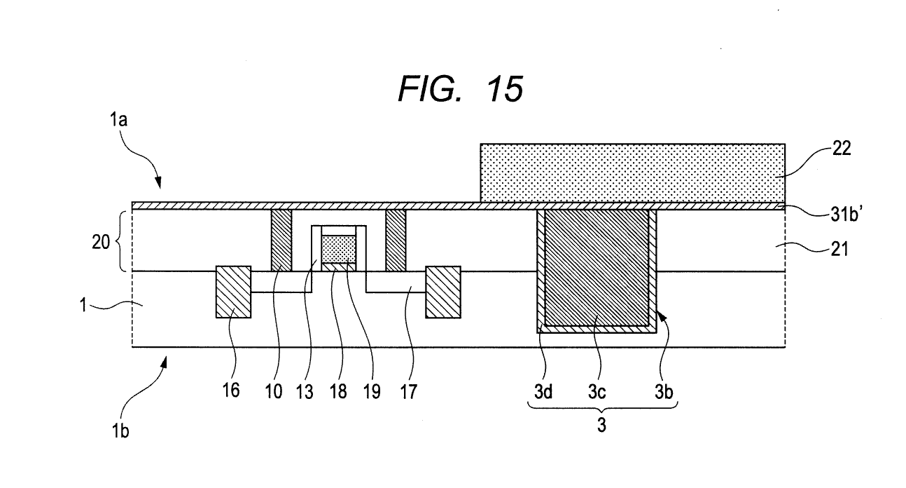

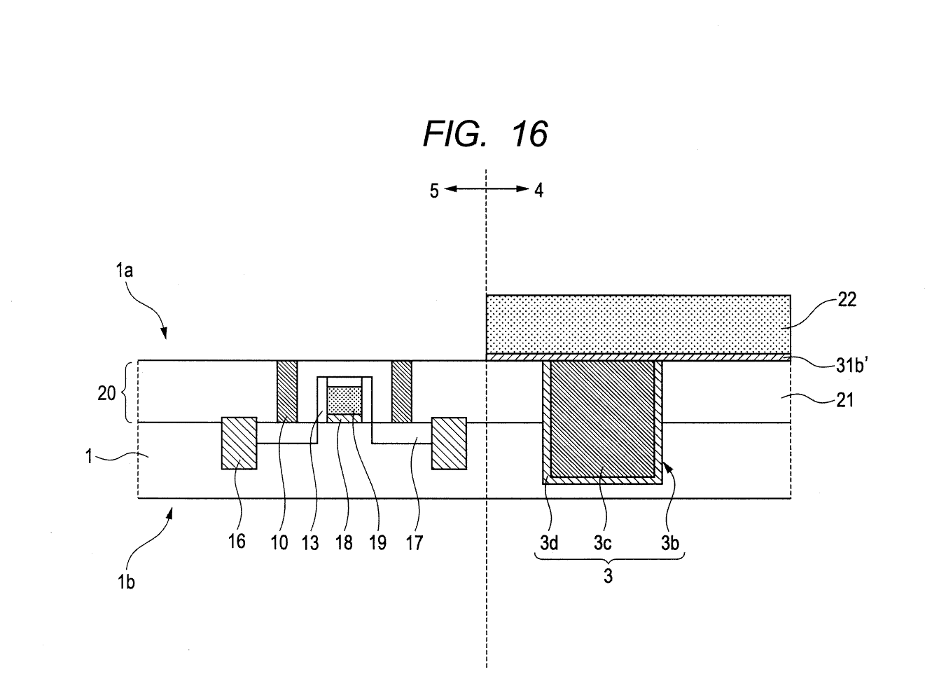

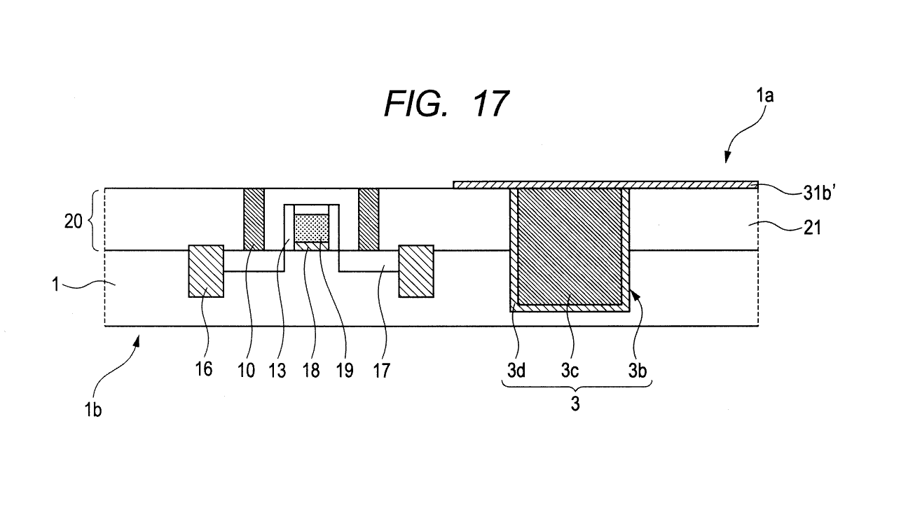

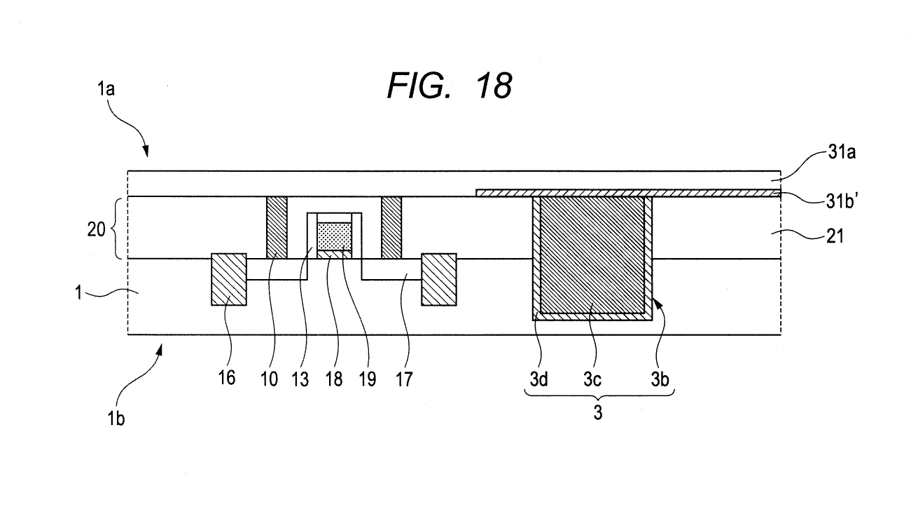

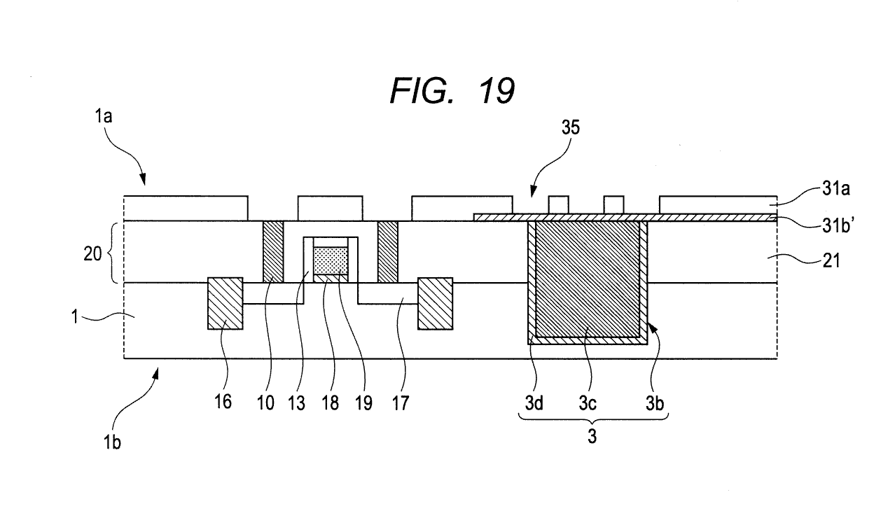

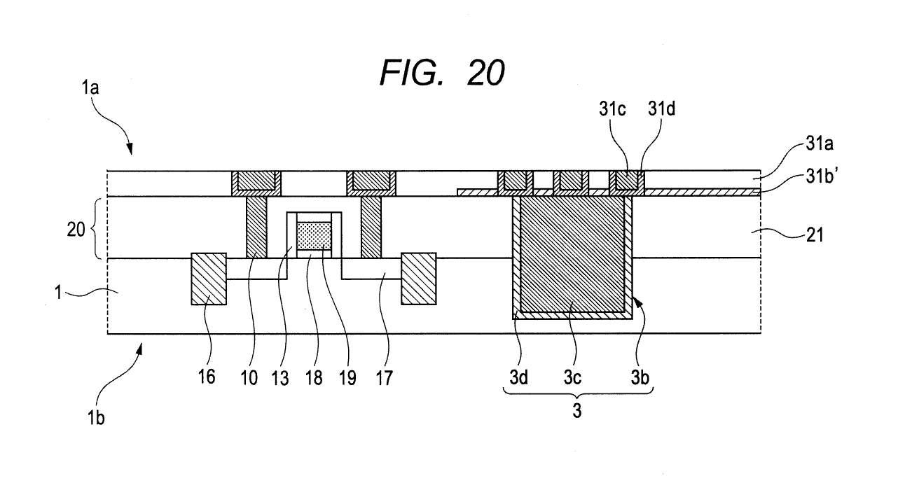

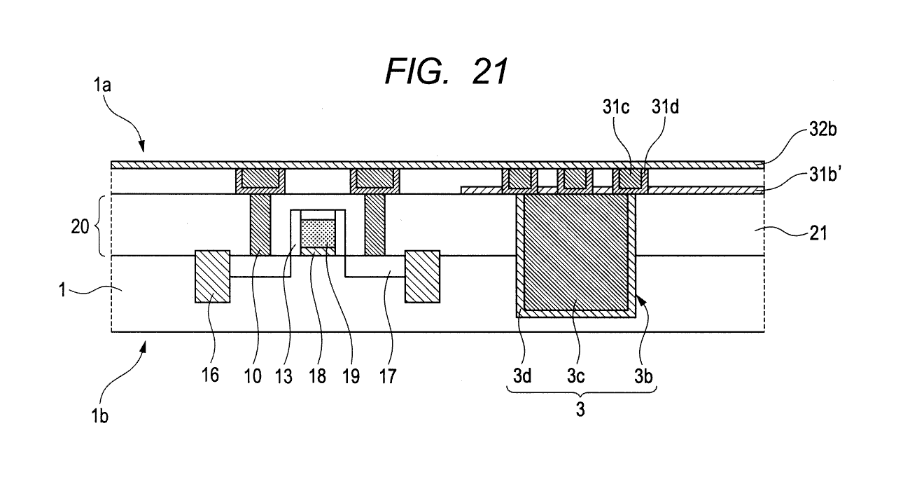

FIG. 12 is a sectional view of a device (at the time of forming a pre-metal wiring layer) showing a process in a method for producing a semiconductor integrated circuit device corresponding to the device structure shown in FIG. 11. FIG. 13 is a sectional view of a device (at the time of finishing filling a through via) showing a process in a method for producing a semiconductor integrated circuit device corresponding to the device structure shown in FIG. 11. FIG. 14 is a sectional view of a device (at the time of forming a copper diffusion barrier insulation film at a through electrode top end interface) showing a process in a method for producing a semiconductor integrated circuit device corresponding to the device structure shown in FIG. 11. FIG. 15 is a sectional view of a device (at the time of forming a resist film for processing a copper diffusion barrier insulation film at a through electrode top end interface) showing a process in a method for producing a semiconductor integrated circuit device corresponding to the device structure shown in FIG. 11. FIG. 16 is a sectional view of a device (at the time of processing a copper diffusion barrier insulation film at a through electrode top end interface) showing a process in a method for producing a semiconductor integrated circuit device corresponding to the device structure shown in FIG. 11. FIG. 17 is a sectional view of a device (at the time of removing a resist film for processing a copper diffusion barrier insulation film at a through electrode top end interface) showing a process in a method for producing a semiconductor integrated circuit device corresponding to the device structure shown in FIG. 11. FIG. 18 is a sectional view of a device (at the time of forming a first layer embedded wiring layer interlayer insulation film) showing a process in a method for producing a semiconductor integrated circuit device corresponding to the device structure shown in FIG. 11. FIG. 19 is a sectional view of a device (at the time of forming apertures for first layer embedded wiring) showing a process in a method for producing a semiconductor integrated circuit device corresponding to the device structure shown in FIG. 11. FIG. 20 is a sectional view of a device (at the time of forming a first layer embedded wiring layer) showing a process in a method for producing a semiconductor integrated circuit device corresponding to the device structure shown in FIG. 11. FIG. 21 is a sectional view of a device (at the time of forming a second layer embedded wiring layer bottom end barrier insulation film) showing a process in a method for producing a semiconductor integrated circuit device corresponding to the device structure shown in FIG. 11. On the basis of those figures, the process in a method for producing a semiconductor integrated circuit device corresponding to the device structure according to Embodiment 2 (only a through via forming region at a through electrode top end interface is covered with a film of a kind of silicon nitride in a via middle method) of the present application is explained.

In the same way as the section 3, as shown in FIG. 12, after a MISFET is formed over the device main surface 1a of a wafer 1, a pre-metal insulation film 21 about 200 nm in thickness for example is formed over the device main surface 1a of the wafer 1 by CVD. Successively, anisotropic dry etching is applied to the side of the device main surface 1a of the wafer 1 in a gas atmosphere containing fluorocarbon for example and contact holes are formed. Successively, a barrier metal and a tungsten member are deposited in sequence over the pre-metal insulation film 21 and in the contact holes. Successively, the barrier metal and the tungsten member outside the contact holes are removed and the surface is flattened by metal CMP treatment.

Successively, as shown in FIG. 13, a section 3 that is to be a through electrode section (refer to a through electrode section periphery cut-out region R1) is formed in a through via forming region 4. As the procedure for example, a non-through hole 3b (a non-through hole to be a through via, the depth is about 100 micrometers for example and the planar shape is about 40 micrometers square for example) ranging from the upper face of the pre-metal insulation film 21 to the middle of the semiconductor substrate 1 is formed by dry etching such as a Bosch process. Successively, an insulation film (a non-through via inner face insulation film 3d to be a through via inner face insulation film) such as a silicon oxide film is deposited over the upper face of the pre-metal insulation film 21 and the inner face and the bottom face of the non-through hole 3b by CVD or the like. Further, a barrier metal film is deposited thereover by CVD, sputtering, or the like and thereafter a copper seed layer and the like are deposited by CVD, sputtering, or the like. Successively, the non-through hole 3b to be a through via is filled with a copper member by electrolytic plating. Here, a non-through electrode 3c to be a through electrode includes the barrier metal film, the copper seed layer, the plated copper member, and the like. Finally, unnecessary members such as the insulation film 3d and the non-through electrode 3c outside the non-through hole 3b are removed by flattening treatment such as CMP.

Successively, as shown in FIG. 14, a copper diffusion preventive insulation barrier film 31b′, namely a silicon nitride film, is formed over nearly the whole upper face of the pre-metal insulation film 21 by plasma CVD or the like. Preferable examples of the film forming conditions of the silicon nitride film are as follows, furnace body used: sheet parallel plate type, gas flow rate: SiH₄ from 10 to 100 sccm (for example, about 30 sccm), NH₃ from 10 to 500 sccm (for example, about 150 sccm), and N₂ from 1,000 to 30,000 sccm (for example, about 3,000 sccm), treatment atmospheric pressure: from 133 to 13,332 Pa (for example, about 1,500 Pa), wafer temperature: from 200° C. to 300° C. (desirably from 250° C. to 300° C. and specifically about 280° C. for example), high-frequency wave power: from 10 to 500 watts at 13.56 MHz (for example, about 100 watts), and film thickness: from 10 to 1,000 nm (for example, about 50 nm). Here, the film forming temperature can be set at about 400° C. as it is generally adopted. By adopting a lower film forming temperature as stated earlier however, it is possible to improve the reliability of a film and the like.

Successively, as shown in FIG. 15, a resist film 22 is applied over the silicon nitride film 31b′ and patterning is applied by lithography. Successively, as shown in FIG. 16, the silicon nitride film 31b′ in the semiconductor element forming region 5 is removed by using the resist film 22 as the mask and applying dry etching for example in an atmosphere containing an etching gas of a kind of fluorocarbon. Thereafter, as shown in FIG. 17, the resist film 22 no longer needed is removed by asking or the like.

Successively, as shown in FIG. 18, a porous SiOC film 31a for example is formed over the pre-metal insulation film 21 and the silicon nitride film 31b′ by plasma CVD. Successively, as shown in FIG. 19, first layer embedded wiring apertures 35 are formed by lithography. Successively, as shown in FIG. 20, a first layer embedded wiring including a first layer embedded wiring layer wiring metal film 31c (for example, copper), a first layer embedded wiring layer barrier metal film 31d (for example, TaN/Ta, Ru, or the like from the bottom layer), and the like is embedded by a single damascene method. Successively, as shown in FIG. 21, an SiCN film 32b for example is formed as a second layer embedded wiring layer bottom end barrier insulation film (a kind of silicon carbide) over the porous SiOC film 31a by plasma CVD. As the copper diffusion barrier insulation film of a kind of silicon carbide, besides an SiCN film, an SiCO film, an SIC film, or a composite film thereof can be used.

The following processes are identical to the processes explained in reference to FIG. 10 in the section 3.

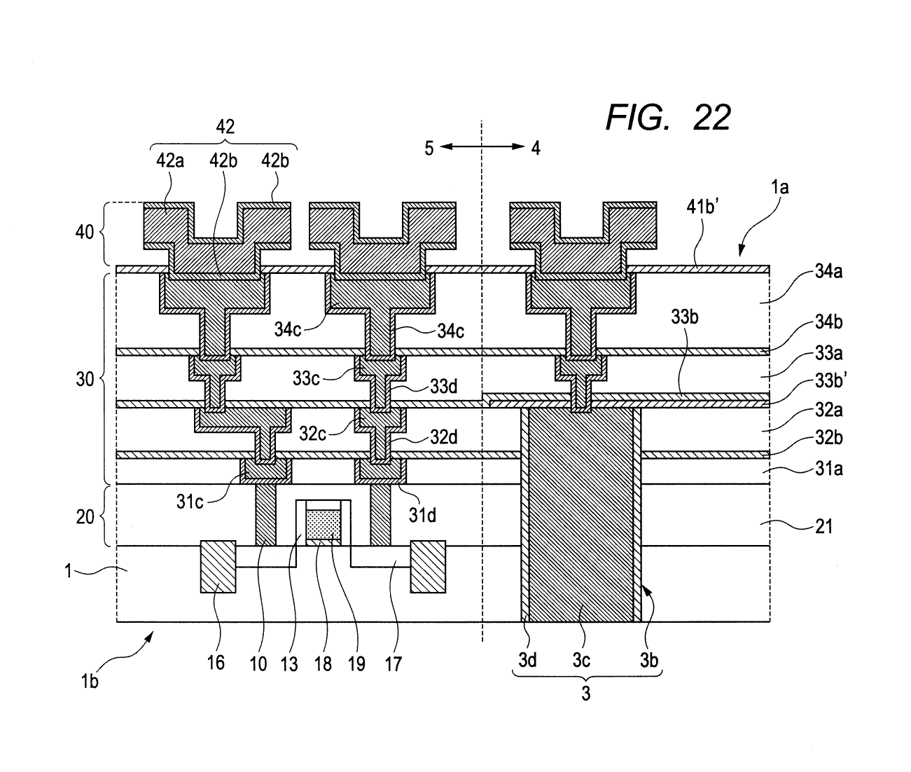

6. Explanations of the cross-sectional structure of a semiconductor chip that is an example of a semiconductor integrated circuit device according to Embodiment 3 (only a through via forming region at a through electrode top end interface is covered with a film of a kind of silicon nitride in a wiring layer middle via method) of the present application (mainly FIG. 22). The first feature of the example explained in this section is that the top end part of a through electrode section 3 is formed at an interlayer interface in a multilayered embedded wiring layer 30 (a wiring layer middle via method). An advantage of the wiring layer middle via method is that the adverse effect to a device on a semiconductor substrate arising when a TSV (Through Silicon Via), namely a through electrode section 3, is formed can be reduced. Although the method is applied to the interface between a second layer embedded wiring layer and a third layer embedded wiring layer here, it is possible likewise to apply the method to the interface between an (N−1)th layer embedded wiring layer (N≧2) and an Nth layer embedded wiring layer.

Further, the second feature is that a copper diffusion barrier insulation film of a kind of silicon nitride 33b′ with which almost a whole through via forming region 4 is covered is formed on the lower side of a copper diffusion barrier insulation film of a kind of silicon carbide 33b with which almost the whole regions of both the through via forming region 4 and a semiconductor element forming region 5 are covered at the interface of an interlayer insulation film corresponding to the top end of a through electrode section 3. An advantage of such a method of covering partially with a copper diffusion barrier insulation film of a kind of silicon nitride is that the reliability of a device can improve while the speed of circuit operation is prevented from lowering in the same way as the example in the section 4.

FIG. 22 is a sectional view (corresponding to the cross section taken on line X-X′ in FIG. 1) of a semiconductor chip that is an example of a semiconductor integrated circuit device according to Embodiment 3 (only a through via forming region at a through electrode top end interface is covered with a film of a kind of silicon nitride in a wiring layer middle via method) of the present application. On the basis of the figure, the cross-sectional structure of a semiconductor chip that is an example of a semiconductor integrated circuit device according to Embodiment 3 (only a through via forming region at a through electrode top end interface is covered with a film of a kind of silicon nitride in a wiring layer middle via method) of the present application is explained.

As shown in FIG. 22, at the interface between a second layer embedded wiring layer interlayer insulation film 32a and a third layer embedded wiring layer interlayer insulation film 33a, a third layer embedded wiring layer bottom end barrier insulation film of a kind of silicon carbide 33b is formed over a third layer embedded wiring layer bottom end barrier insulation film of a kind of silicon nitride 33b′, with which only a through via forming region 4 is covered, and the second layer embedded wiring layer interlayer insulation film 32a, so as to cover almost the whole regions of the through via forming region 4 and a semiconductor element forming region 5.

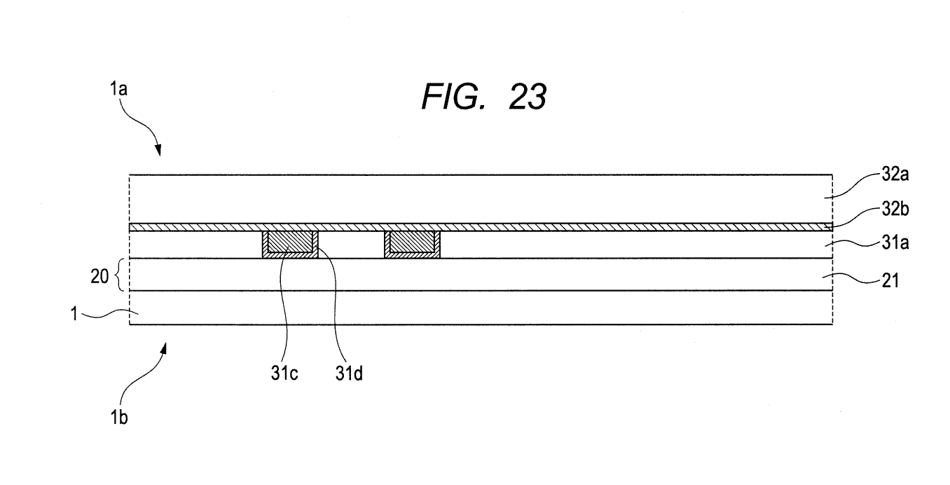

7. Explanations of a process in a method for producing a semiconductor integrated circuit device corresponding to the device structure according to Embodiment 3 (only a through via forming region at a through electrode top end interface is covered with a film of a kind of silicon nitride in a wiring layer middle via method) of the present application (mainly FIGS. 23 to 33). The production method of this section corresponds to the device structure of the section 6. The production method of this section is similar to the production method (a pre-metal wiring advance method) explained in the section 5 but a feature thereof is that a TSV, namely a through electrode section, is formed in advance (a local TSV advance method). Here, it is also possible to start to form a through electrode section after a wiring layer is completed in advance in the same way as the section 5 (a wiring advance method). Here, an advantage of the local TSV advance method is that, when it is applied to a wiring layer middle via method, excessive polishing of a copper wiring and the like in a semiconductor element forming region 5 at a CMP process that is likely to occur in a wiring advance method can be avoided. Further, it goes without saying that the local TSV advance method can be applied similarly to the case of another section.

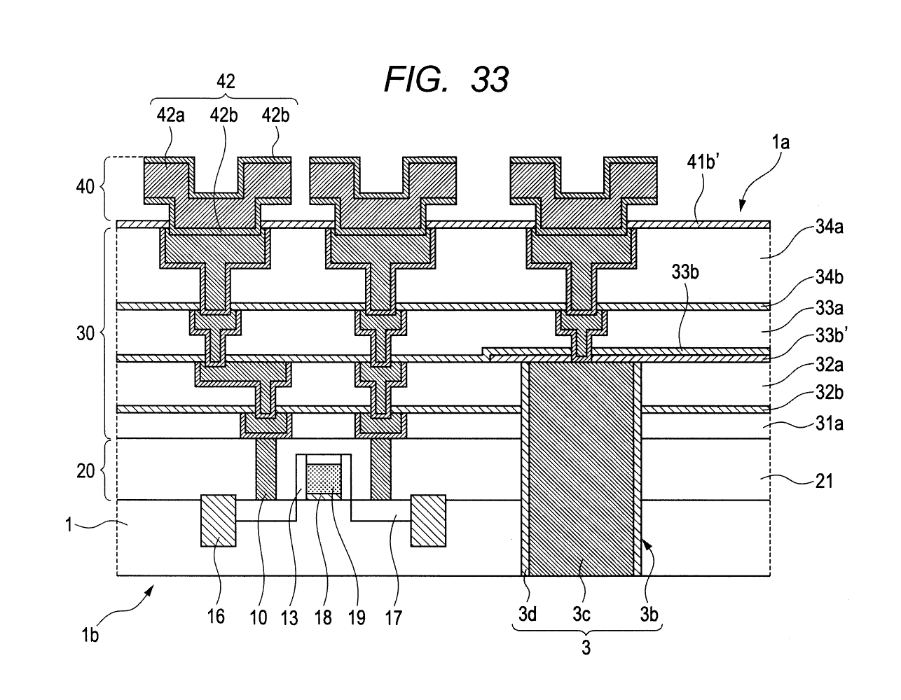

In the processes explained here, a device structure on a semiconductor substrate surface is omitted except FIG. 33 for convenience of pictorial display.

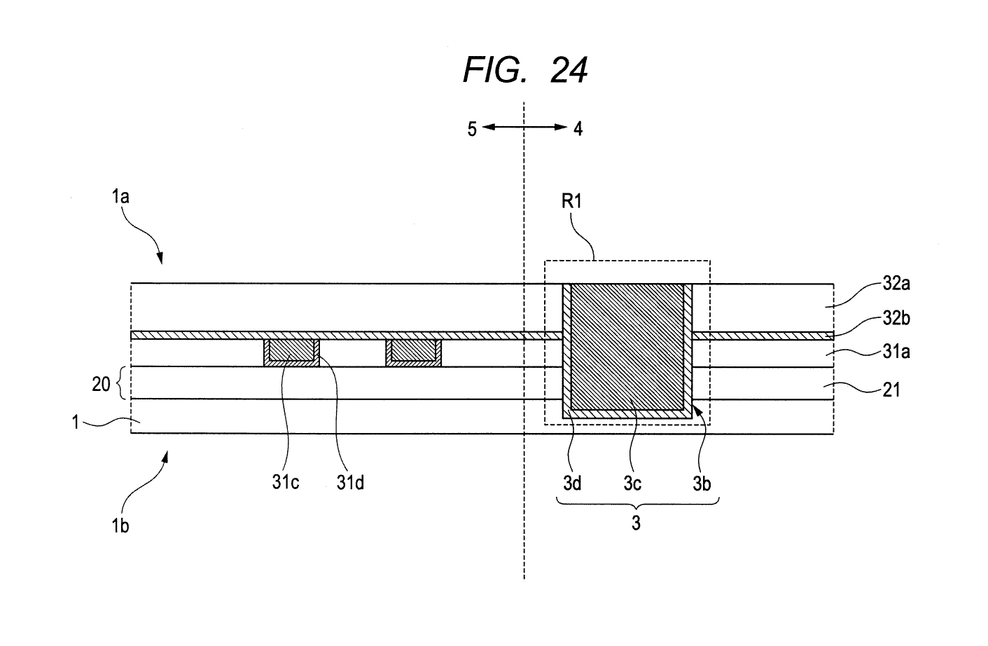

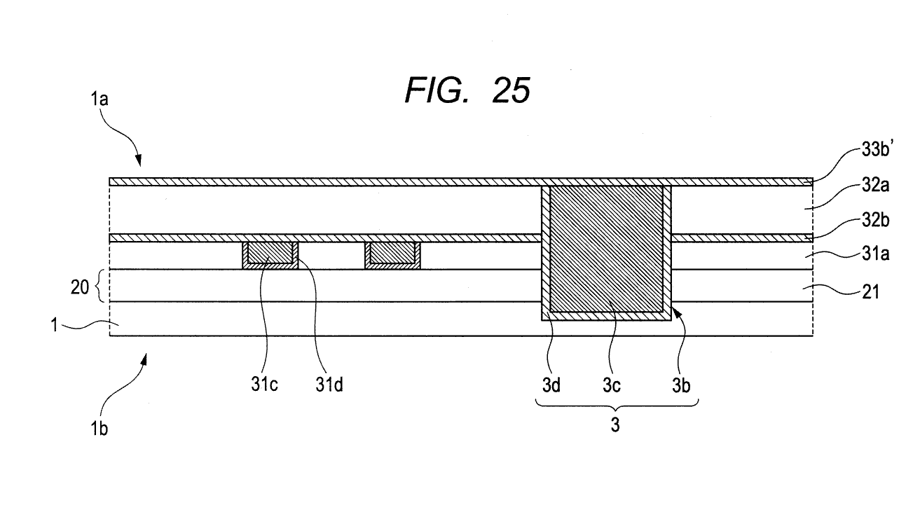

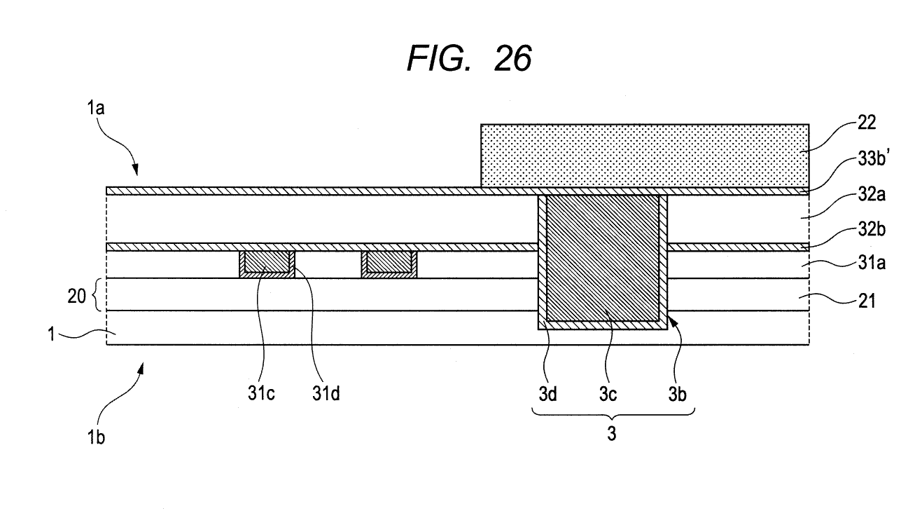

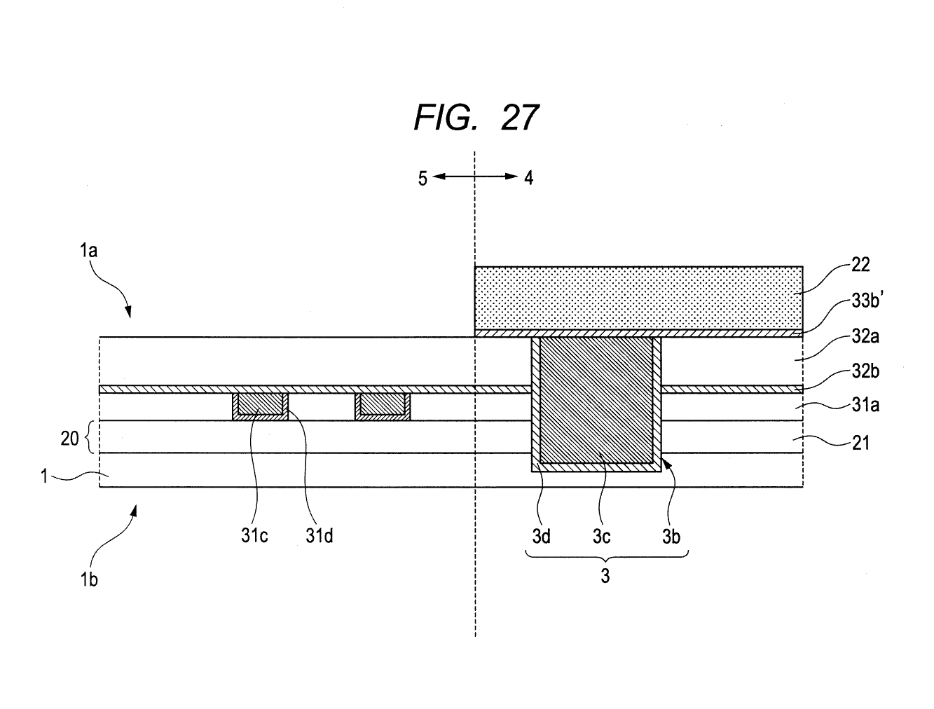

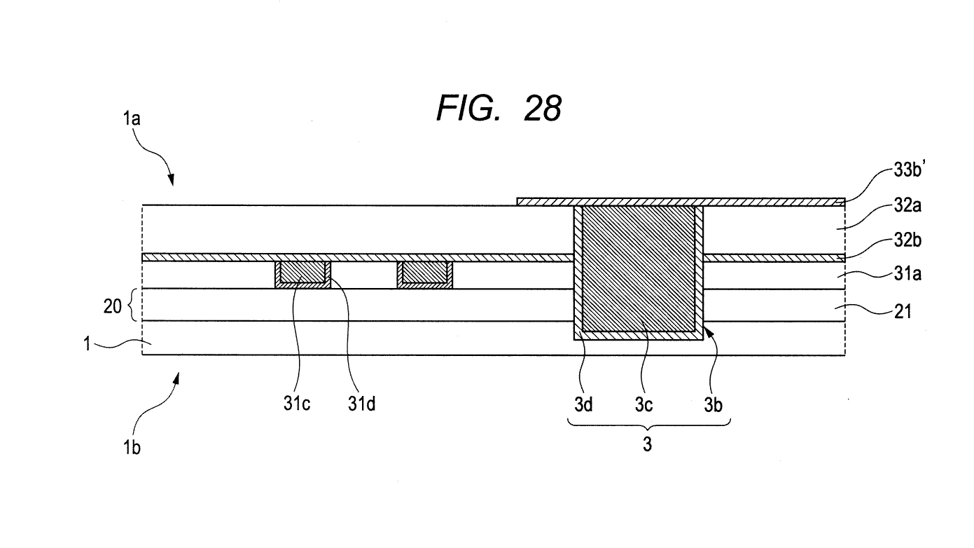

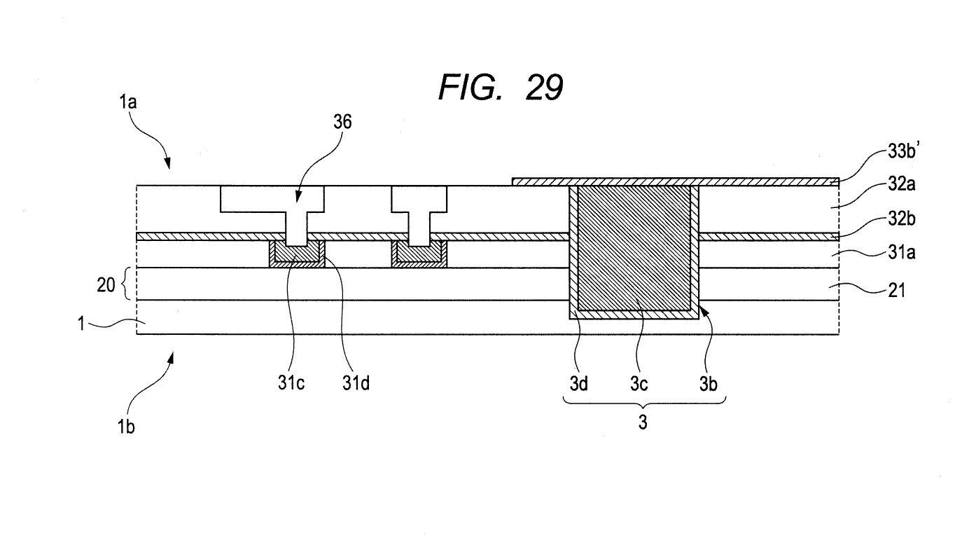

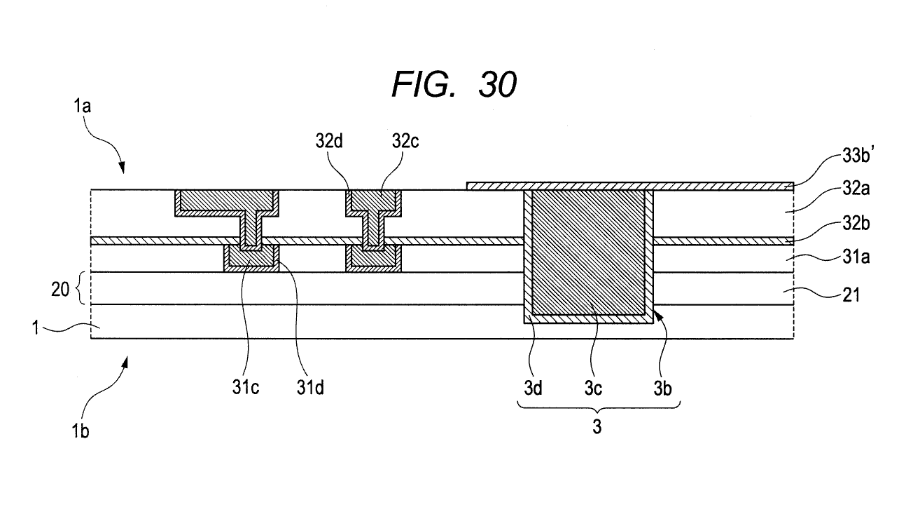

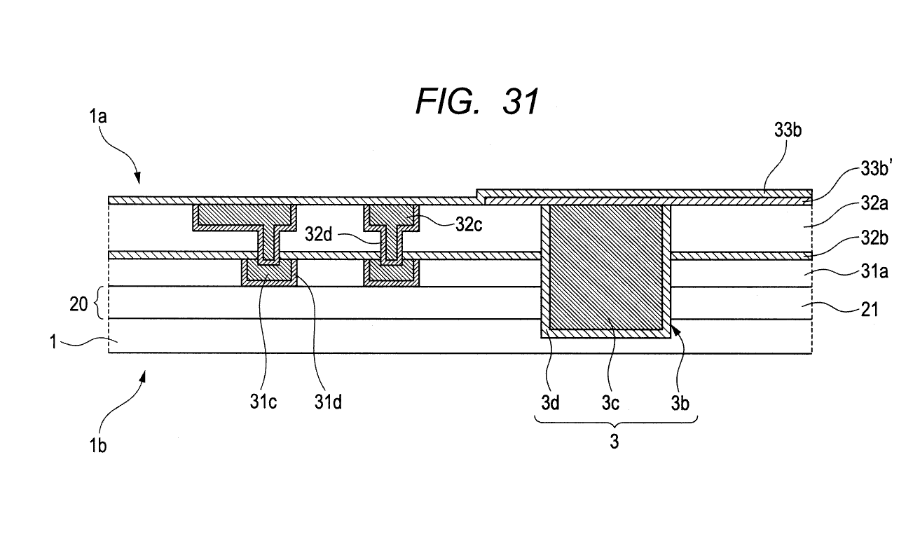

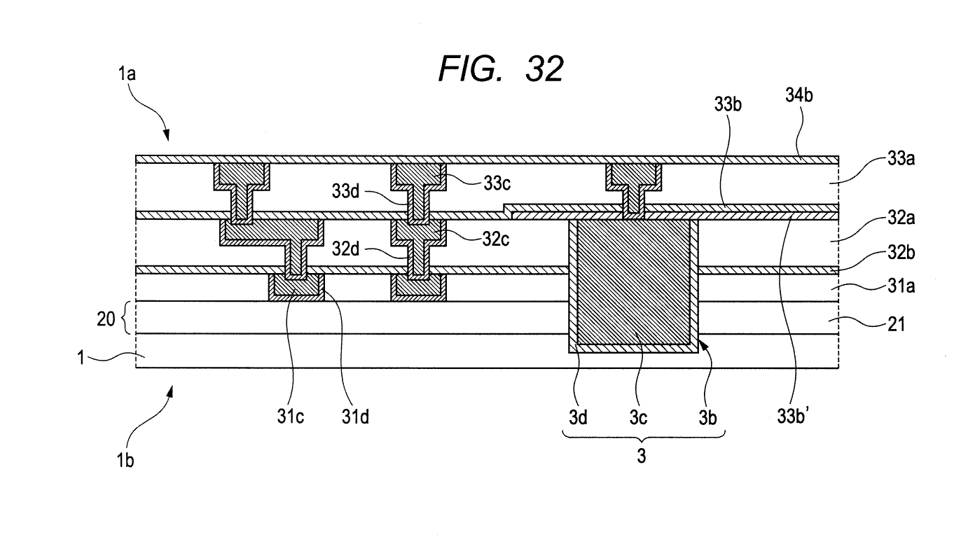

FIG. 23 is a sectional view of a device (at the time of forming a pre-metal insulation film) showing a process in a method for producing a semiconductor integrated circuit device corresponding to the device structure shown in FIG. 22. FIG. 24 is a sectional view of a device (at the time of finishing filling a through via) showing a process in a method for producing a semiconductor integrated circuit device corresponding to the device structure shown in FIG. 22. FIG. 25 is a sectional view of a device (at the time of forming a copper diffusion barrier insulation film at a through electrode top end interface) showing a process in a method for producing a semiconductor integrated circuit device corresponding to the device structure shown in FIG. 22. FIG. 26 is a sectional view of a device (at the time of forming a resist film for processing a copper diffusion barrier insulation film at a through electrode top end interface) showing a process in a method for producing a semiconductor integrated circuit device corresponding to the device structure shown in FIG. 22. FIG. 27 is a sectional view of a device (at the time of processing a copper diffusion barrier insulation film at a through electrode top end interface) showing a process in a method for producing a semiconductor integrated circuit device corresponding to the device structure shown in FIG. 22. FIG. 28 is a sectional view of a device (at the time of removing a resist film for processing a copper diffusion barrier insulation film at a through electrode top end interface) showing a process in a method for producing a semiconductor integrated circuit device corresponding to the device structure shown in FIG. 22. FIG. 29 is a sectional view of a device (at the time of forming apertures for first layer embedded wiring) showing a process in a method for producing a semiconductor integrated circuit device corresponding to the device structure shown in FIG. 22. FIG. 30 is a sectional view of a device (at the time of forming a first layer embedded wiring layer) showing a process in a method for producing a semiconductor integrated circuit device corresponding to the device structure shown in FIG. 22. FIG. 31 is a sectional view of a device (at the time of forming a second layer embedded wiring layer bottom end barrier insulation film) showing a process in a method for producing a semiconductor integrated circuit device corresponding to the device structure shown in FIG. 22. FIG. 32 is a sectional view of a device (at the time of forming a third layer embedded wiring layer bottom end barrier insulation film) showing a process in a method for producing a semiconductor integrated circuit device corresponding to the device structure shown in FIG. 22. FIG. 33 is a sectional view of a device (at the time of forming a pad wiring layer) showing a process in a method for producing a semiconductor integrated circuit device corresponding to the device structure shown in FIG. 22. On the basis of those figures, the process in a method for producing a semiconductor integrated circuit device corresponding to the device structure according to Embodiment 3 (only a through via forming region at a through electrode top end interface is covered with a film of a kind of silicon nitride in a wiring layer middle via method) of the present application is explained.

In the same way as the section 5, as shown in FIG. 12, after a MISFET is formed over the device main surface 1a of a wafer 1, a pre-metal insulation film 21 about 200 nm in thickness for example is formed over the device main surface 1a of the wafer 1 by CVD. Successively, anisotropic dry etching is applied to the side of the device main surface 1a of the wafer 1 in a gas atmosphere containing fluorocarbon for example and contact holes are formed. Successively, a barrier metal and a tungsten member are deposited in sequence over the pre-metal insulation film 21 and in the contact holes. Successively, the barrier metal and the tungsten member outside the contact holes are removed and the surface is flattened by metal CMP treatment.

Successively, as shown in FIG. 23, a porous SiOC film 31a for example is formed over the pre-metal insulation film 21 by plasma CVD. Successively, a first layer embedded wiring including a first layer embedded wiring layer wiring metal film 31c (for example, copper), a first layer embedded wiring layer barrier metal film 31d (for example, TaN/Ta, Ru, or the like from the bottom layer), and the like is embedded by a single damascene method. Successively, an SiCN film 32b for example is formed as a second layer embedded wiring layer bottom end barrier insulation film (a kind of silicon carbide) over the porous SiOC film 31a by plasma CVD. As the copper diffusion barrier insulation film of a kind of silicon carbide, besides an SiCN film, an SiCO film, an SIC film, or a composite film thereof can be used. Further, a porous SiOC film 32a for example is formed over the SiCN film 32b by plasma CVD.

Successively, as shown in FIG. 24, a section 3 that is to be a through electrode section (refer to a through electrode section periphery cut-out region R1) is formed in a through via forming region 4. As the procedure for example, a non-through hole 3b (a non-through hole to be a through via, the depth is about 100 micrometers for example and the planar shape is about 40 micrometers square for example) ranging from the upper face of the porous SiOC film 32a to the middle of the semiconductor substrate 1 is formed by dry etching such as a Bosch process. Successively, an insulation film (a non-through via inner face insulation film 3d to be a through via inner face insulation film) such as a silicon oxide film is deposited over the upper face of the porous SiOC film 32a and the inner face and the bottom face of the non-through hole 3b by CVD or the like. Further, a barrier metal film is deposited thereover by CVD, sputtering, or the like and thereafter a copper seed layer and the like are deposited by CVD, sputtering, or the like. Successively, the non-through hole 3b to be a through via is filled with a copper member by electrolytic plating. Here, a non-through electrode 3c to be a through electrode includes the barrier metal film, the copper seed layer, the plated copper member, and the like. Finally, unnecessary members such as the insulation film 3d and the non-through electrode 3c outside the non-through hole 3b are removed by flattening treatment such as CMP.

Successively, as shown in FIG. 25, a copper diffusion preventive insulation barrier film 33b′, namely a silicon nitride film, is formed over nearly the whole upper face of the porous SiOC film 32a by plasma CVD or the like. Preferable examples of the film forming conditions of the silicon nitride film are as follows, furnace body used: sheet parallel plate type, gas flow rate: SiH₄ from 10 to 100 sccm (for example, about 30 sccm), NH₃ from 10 to 500 sccm (for example, about 150 sccm), and N₂ from 1,000 to 30,000 sccm (for example, about 3,000 sccm), treatment atmospheric pressure: from 133 to 13,332 Pa (for example, about 1,500 Pa), wafer temperature: from 200° C. to 300° C. (desirably from 250° C. to 300° C. and specifically about 280° C. for example), high-frequency wave power: from 10 to 500 watts at 13.56 MHz (for example, about 100 watts), and film thickness: from 10 to 1,000 nm (for example, about 150 nm). Here, the film forming temperature can be set at about 400° C. as it is generally adopted. By adopting a lower film forming temperature as stated earlier however, it is possible to reduce the deposition change of a copper member configuring a through electrode caused by heat and thereby prevent a copper diffusion barrier insulation film formed over it from cracking and the like. If the temperature reduction is excessive however, the quality of the copper diffusion barrier insulation film deteriorates.

Successively, as shown in FIG. 26, a resist film 22 is applied over the silicon nitride film 33b′ and patterning is applied by lithography. Successively, as shown in FIG. 27, the silicon nitride film 33b′ in the semiconductor element forming region 5 is removed by using the resist film 22 as the mask and applying dry etching for example in an atmosphere containing an etching gas of a kind of fluorocarbon. Thereafter, as shown in FIG. 28, the resist film 22 no longer needed is removed by asking or the like.

Successively, as shown in FIG. 29, second layer embedded wiring apertures 36 are formed by lithography. Successively, as shown in FIG. 30, a second layer embedded wiring including a second layer embedded wiring layer wiring metal film 32c (for example, copper), a second layer embedded wiring layer barrier metal film 32d (for example, TaN/Ta, Ru, or the like from the bottom layer), and the like is embedded by a dual damascene method. Since the thickness of the silicon nitride film 33b′ reduces on this occasion, it is necessary to increase the thickness at the preceding process to the extent corresponding to the thickness reduction. Successively, as shown in FIG. 31, an SiCN film 33b for example (the thickness is about 50 nm for example) is formed as a third layer embedded wiring layer bottom end barrier insulation film (a kind of silicon carbide) over the porous SiOC film 32a and the silicon nitride film 33b′ by plasma CVD. As the copper diffusion barrier insulation film of a kind of silicon carbide, besides an SiCN film, an SiCO film, an SIC film, or a composite film thereof can be used.

Successively, as shown in FIG. 32, a nonporous SiOC film 33a for example is formed over the SiCN film 33b by plasma CVD. Successively, almost in the same way as above, a third layer embedded wiring including a third layer embedded wiring layer wiring metal film 33c (for example, copper), a third layer embedded wiring layer barrier metal film 33d (for example, TaN/Ta, Ru, or the like from the bottom layer), and the like is embedded by a dual damascene method. Successively, an SiCN film 34b for example is formed as a fourth layer embedded wiring layer bottom end barrier insulation film (a kind of silicon carbide) over the nonporous SiOC film 33a by plasma CVD.

Then likewise, as shown in FIG. 33, a TEOS silicon oxide film 34a for example is formed over the SiCN film 34b by plasma CVD. Successively, almost in the same way as above, a fourth layer embedded wiring including a fourth layer embedded wiring layer wiring metal film 34c (for example, copper), a fourth layer embedded wiring layer barrier metal film 34d (for example, TaN/Ta, Ru, or the like from the bottom layer), and the like is embedded by a dual damascene method. Successively, a silicon nitride film 41b′ for example is formed as a pad wiring layer bottom end barrier insulation film (a kind of silicon nitride) over the TEOS silicon oxide film 34a by plasma CVD.

A pad wiring layer 40 is formed thereafter.

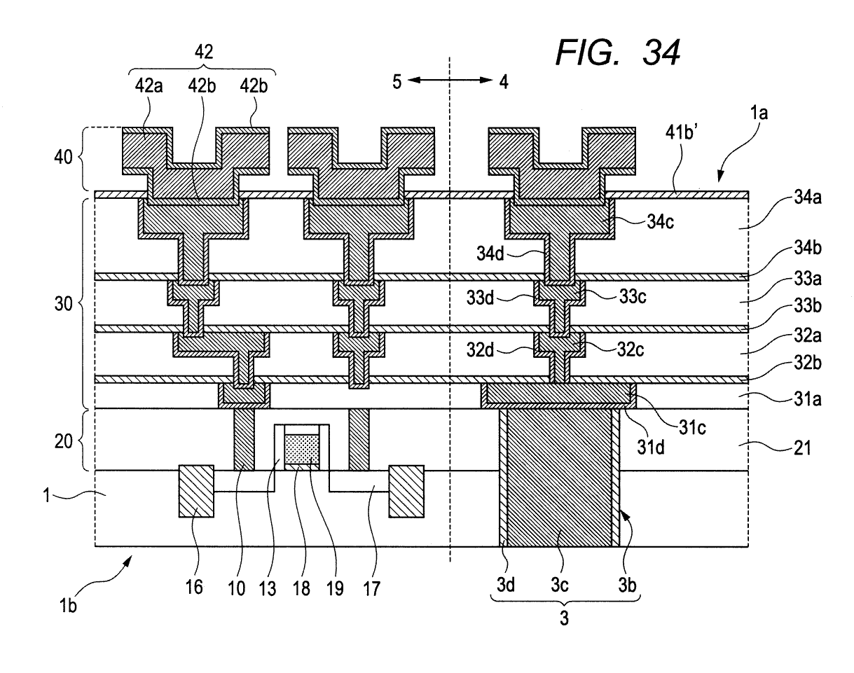

8. Explanations of the cross-sectional structure of a semiconductor chip that is an example of a semiconductor integrated circuit device according to Embodiment 4 (a copper diffusion preventive insulation film at a through electrode top end interface is omitted in a via middle method) of the present application (mainly FIG. 34). The example in this section has a structure formed by: omitting the first layer embedded wiring layer bottom end barrier insulation film of a kind of silicon nitride 31b′ (refer to FIG. 3) at the interface between the pre-metal insulation film 21 and the first layer embedded wiring layer interlayer insulation film 31a in the device structure explained with FIG. 3 of the section 2; and covering the whole upper face of the through electrode section 3 with the first layer embedded wiring layer barrier metal film 31d. By so doing, an insulation film of a high electric permittivity can be removed also from the semiconductor element forming region 5 and hence it is possible to attempt to increase the speed of circuit operation. Here, in comparison with the example shown in FIG. 3, copper or the like may undesirably diffuse when the first layer embedded wiring layer interlayer insulation film 31a is formed and processed but, since the upper face of the through electrode 3c is covered with the barrier metal 31d immediately thereafter, it is estimated that the influence is comparatively small. A disadvantage however is that the first layer wiring over the through electrode 3 cannot be divided unlike the example shown in FIG. 3 and the like. When the first layer wiring over the through electrode 3 is divided like the examples shown in FIGS. 3 and 11, a dimension close to the dimension of the first layer wiring formed in the semiconductor element forming region 5 may be adopted. Consequently the production is facilitated.

FIG. 34 is a sectional view (corresponding to the cross section taken on line X-X′ in FIG. 1) of a semiconductor chip that is an example of a semiconductor integrated circuit device according to Embodiment 4 (a copper diffusion preventive insulation film at a through electrode top end interface is omitted in a via middle method) of the present application. On the basis of the figure, the cross-sectional structure of a semiconductor chip that is an example of a semiconductor integrated circuit device according to Embodiment 4 (a copper diffusion preventive insulation film at a through electrode top end interface is omitted in a via middle method) of the present application is explained.

As shown in FIG. 34, a copper diffusion barrier insulation film is not formed in both the regions of the through via forming region 4 and the semiconductor element forming region 5 at the interface between the pre-metal insulation film 21 and the first layer embedded wiring layer interlayer insulation film 31a. Meanwhile, the whole upper face of the through electrode section 3 is covered with the monolithic through electrode section upper first layer wiring 31 (specifically, the whole upper face of the through electrode section 3 is covered with the barrier metal 31d). Consequently, the area of the through electrode section upper first layer wiring 31 is larger than that of the upper face of the through electrode section 3.

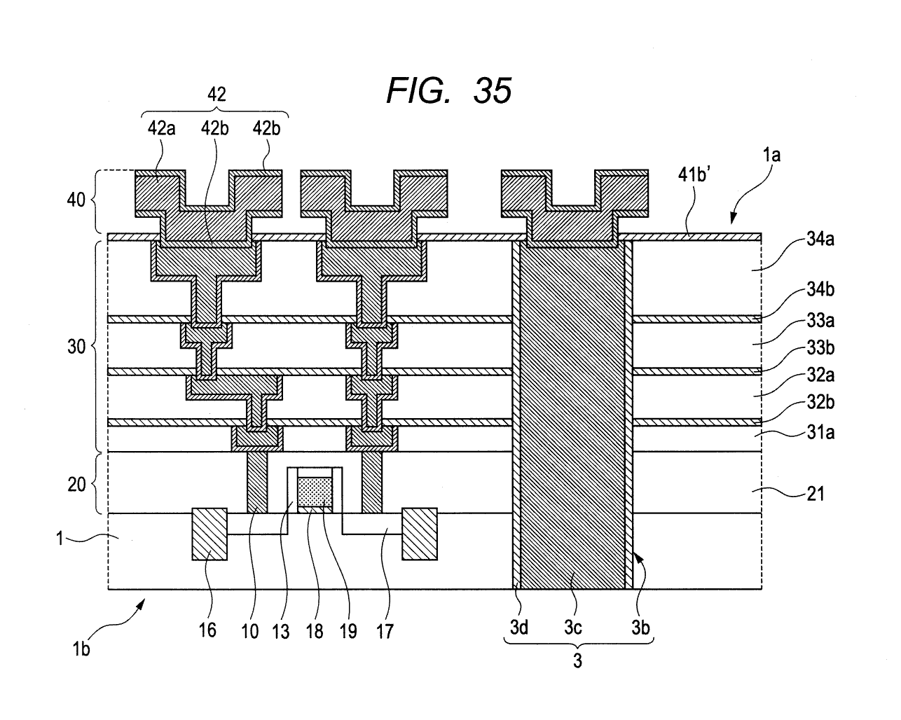

9. Explanations of the cross-sectional structure of a semiconductor chip produced by a method for producing a semiconductor integrated circuit device according to Embodiment 5 (a whole through electrode top end interface is covered with a film of a kind of silicon nitride in a via last method) of the present application (mainly FIG. 35). In the example explained here, formation of the through electrode section 3 is after the uppermost layer of a multilayered embedded wiring layer 30, namely the fourth layer embedded wiring layer interlayer insulation film 34a in this example, is formed and before or after the wiring of the layer is completely formed. On this occasion, the expansion of the through electrode or the through electrode member 3c may increase undesirably and hence it is effective to form the silicon nitride film 41b′ (FIG. 35) at a comparatively low temperature as it has been explained earlier.

The device structure is similar to the example shown in FIG. 34 but the structures of the through electrode section 3 and the circumference thereof in the through via forming region 4 are different. The advantage of the structures is that the through electrode section 3 can be formed while devices over a semiconductor substrate are scarcely influenced although the load in the processing of the through electrode section 3 is large. Further, another advantage is that the silicon nitride film 41b′ at the interface between the interlayer insulation film 34a of the uppermost layer of the multilayered embedded wiring layer 30 that is generally widely used and the pad wiring layer 40 can be used also as the copper diffusion barrier insulation film over the upper face of the through electrode section 3. By the structure, it is not necessary to use an insulation film of a kind of silicon nitride of a high electric permittivity at the lower layer wiring region requiring high speed operation, namely the interface between wiring layers in the multilayered embedded wiring layer 30 and the interface between the multilayered embedded wiring layer 30 and the pre-metal wiring layer 20, and hence it is possible to secure the high speed operation of a circuit.

FIG. 35 is a sectional view (corresponding to the section taken on line X-X′ in FIG. 1) of a semiconductor chip produced by a method for producing a semiconductor integrated circuit device according to Embodiment 5 (a whole through electrode top end interface is covered with a film of a kind of silicon nitride in a via last method) of the present application. On the basis of the figure, the cross-sectional structure of a semiconductor chip produced by a method of producing a semiconductor integrated circuit device according to Embodiment 5 (a whole through electrode top end interface is covered with a film of a kind of silicon nitride in a via last method) of the present application is explained.

As shown in FIG. 35 in comparison with FIG. 3, the first layer embedded wiring layer bottom end barrier insulation film of a kind of silicon nitride 31b′ is not formed and the top end of the through electrode section 3 is formed at the interface between the fourth layer embedded wiring layer interlayer insulation film 34a and the pad wiring layer 40.

Here, the production method is nearly the same as the production method used for the semiconductor element forming region 5 shown in FIGS. 4 and 7 to 10 of the section 3 except that the first layer embedded wiring layer bottom end barrier insulation film of a kind of silicon nitride 31b′ is not formed. Here, the difference from FIG. 10 is that formation of the through electrode section 3 starts when the fourth layer embedded wiring layer interlayer insulation film 34a is formed completely or the fourth layer embedded wiring layer is formed completely.

10. Explanations of Modified Example 1 (a recess part is formed by plating) of a through electrode top end structure common to the embodiments of the present application (mainly FIGS. 36 to 38). This section and the succeeding section are modified examples of the device structure and the production method thereof that have been explained heretofore. The through electrode embedding process that will be explained hereunder corresponds to the basic process of the device structure and the production method thereof that have been explained heretofore if the recess part 24 (the following plating condition 1) is excluded. Consequently, the through electrode embedding process that is explained in this section and the succeeding section can also be applied to all of the examples that have been explained heretofore.

A feature of the example in this section from the aspect of structure is that a recess part 24 is formed at the top end face of a through electrode 3 and the recess part 24 alleviates thermal stress and a feature thereof from the aspect of production method is that the recess part 24 is formed automatically in a copper electrolytic plating process.

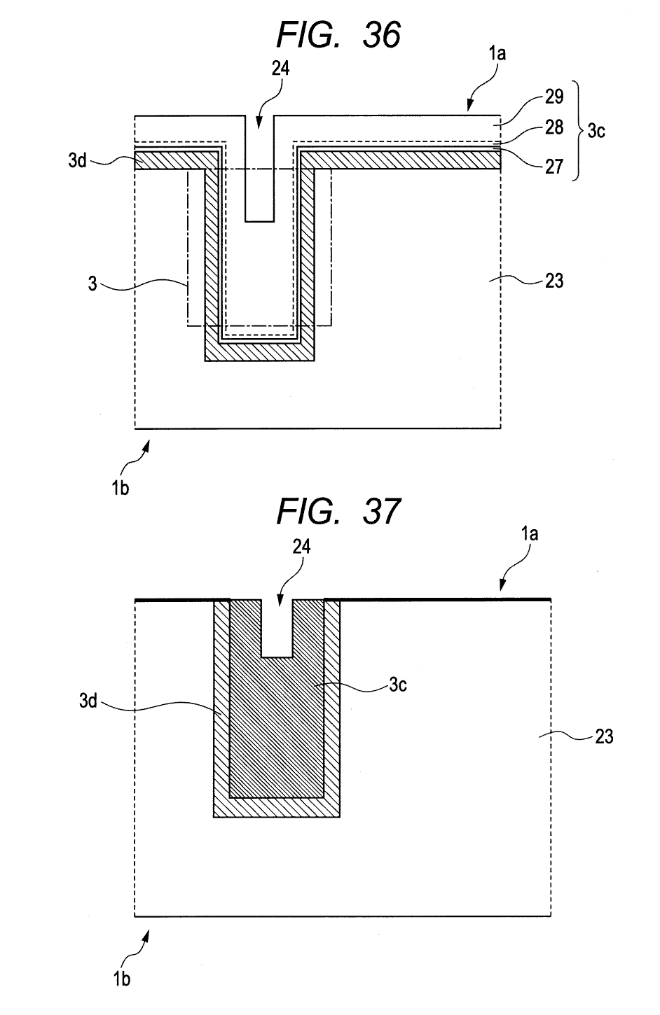

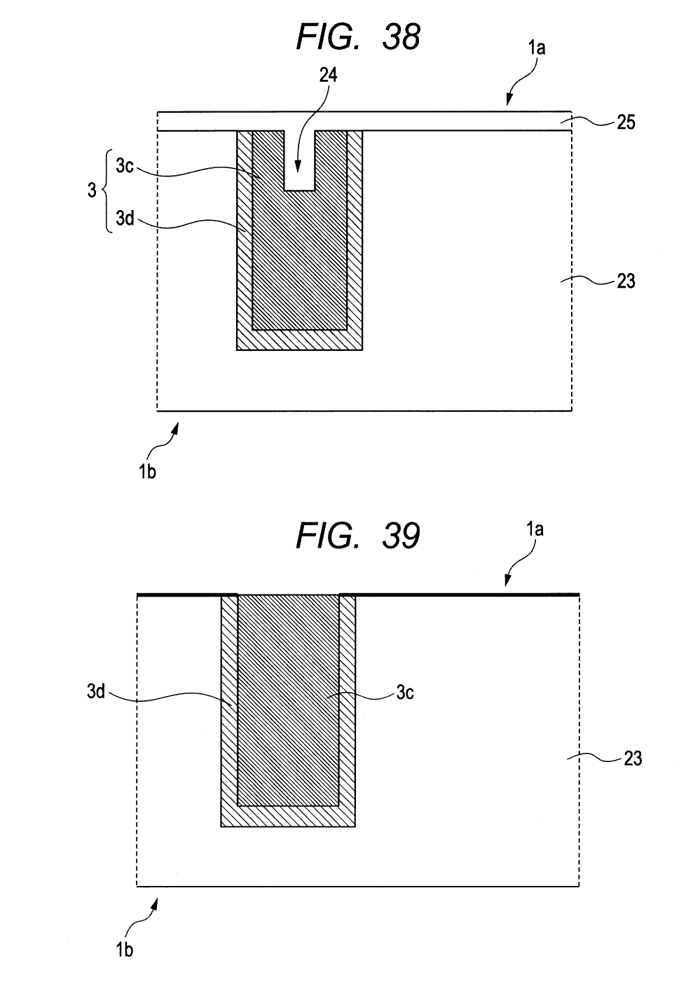

FIG. 36 is a sectional view of a through electrode section (at the time of finishing copper plating) showing Modified Example 1 (a recess part is formed by plating) of a through electrode top end structure and the process thereof common to the embodiments of the present application. FIG. 37 is a sectional view of a through electrode section (at the time of flattening a surface) showing Modified Example 1 (a recess part is formed by plating) of a through electrode top end structure and the process thereof common to the embodiments of the present application. FIG. 38 is a sectional view of a through electrode section (at the time of forming a metal diffusion barrier insulation film of a kind of silicon nitride) showing Modified Example 1 (a recess part is formed by plating) of a through electrode top end structure and the process thereof common to the embodiments of the present application. On the basis of those figures, Modified Example 1 (a recess part is formed by plating) of a through electrode top end structure common to the embodiments of the present application is explained.

As shown in FIG. 36, a part 3 that is to be a through electrode section is formed in a through via forming region 4 (refer to a through electrode section periphery cut-out region R1 in FIG. 5, 13, 24, or another). As the procedure for example, a non-through hole 3b (a non-through hole to be a through via, the depth is about 100 micrometers for example and the planar shape is about 40 micrometers square for example) ranging from the upper face of a semiconductor substrate and an insulation film 23 thereover to the middle of a semiconductor substrate 1 is formed by dry etching such as a Bosch process (for example, alternately repeating isotropic etching by SF₆ or the like and anisotropic etching by C₄F₈ or the like). Successively, an insulation film (a non-through via inner face insulation film 3d to be a through via inner face insulation film) such as a silicon oxide film is deposited over the upper face of the semiconductor substrate and the insulation film 23 thereon and the inner face and the bottom face of the non-through hole 3b by CVD or the like. Further, a barrier metal film 27, a copper seed layer 28, and others are deposited thereover by CVD, sputtering, or the like.

Successively, the non-through hole 3b to be a through via is filled with a copper member 29 by electrolytic plating. Here, a non-through electrode 3c to be a through electrode includes the barrier metal film 27, the copper seed layer 28, the plated copper member 29, and the like.

An example of the conditions of copper electrolytic plating is as follows. That is, (1) a preferable example of ordinary plating conditions (the case of not forming a recess) is as follows (this example represents standard conditions in the case of not forming a recess by plating at the section 11 and the preceding sections), plating current density: about 50 to 300 mA/dm², plating time: about 2 hours and 15 minutes, and plating film thickness: about 30 micrometers in blanket film equivalent (deposition thickness at a closed-end part). (2) A preferable example of the conditions of forming a recess is as follows, plating current density: about 50 to 300 mA/dm², plating time: about 1 hour and 30 minutes, and plating film thickness: about 20 micrometers in blanket film equivalent (deposition thickness at a closed-end part). By so doing, a recess part about 5 micrometers in width and about 10 micrometers in depth is formed.

Successively, as shown in FIG. 37, unnecessary members such as the insulation film 3d and the non-through electrode 3c outside the non-through hole 3b are removed by flattening treatment such as CMP. The final dimension of the recess 24 is about 5 micrometers in width and about 2 to 5 micrometers in depth.

Successively, as shown in FIG. 38, a metal diffusion barrier insulation film of a kind of silicon nitride 25 is formed by plasma CVD or the like so as to cover the upper face of the semiconductor substrate and the insulation film 23 thereover and the upper face of the through electrode section 3 and fill the interior of the recess part 24.

11. Explanations of Modified Example 2 (a recess part is formed by lithography) of a through electrode top end structure common to the embodiments of the present application (mainly FIGS. 39 to 44). A feature of the example in this section from the aspect of structure is that a recess part 24 is formed at the top end face of a through electrode 3 and the recess part 24 alleviates thermal stress and a feature thereof from the aspect of production method is that the recess part 24 is formed by lithography after a copper member and the like are embedded into a non-through hole to be a through via. On this occasion therefore, a recess part 24 having optimum shape and dimension can be formed independently from a plating process.

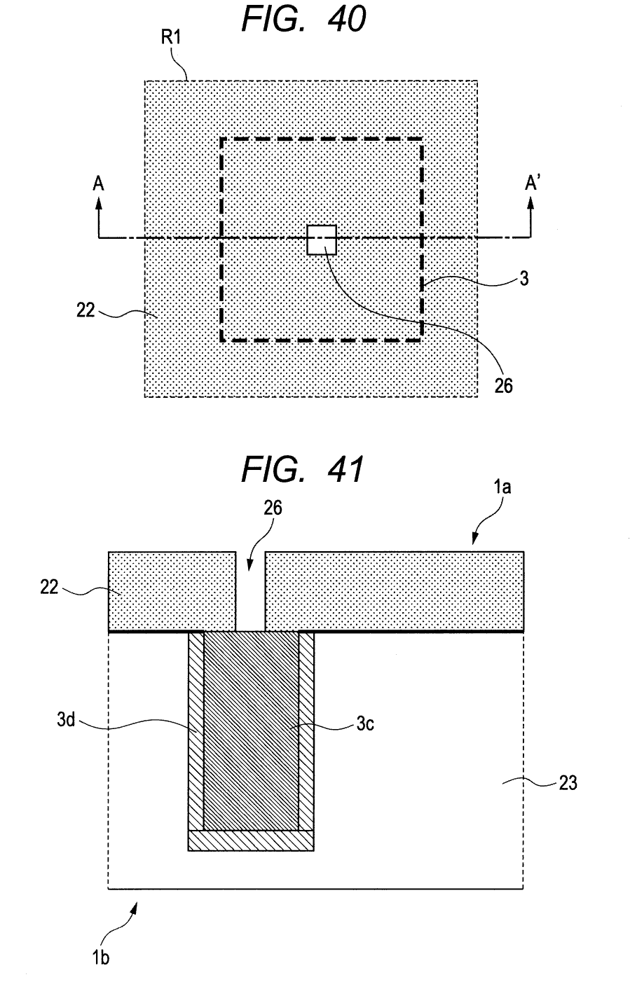

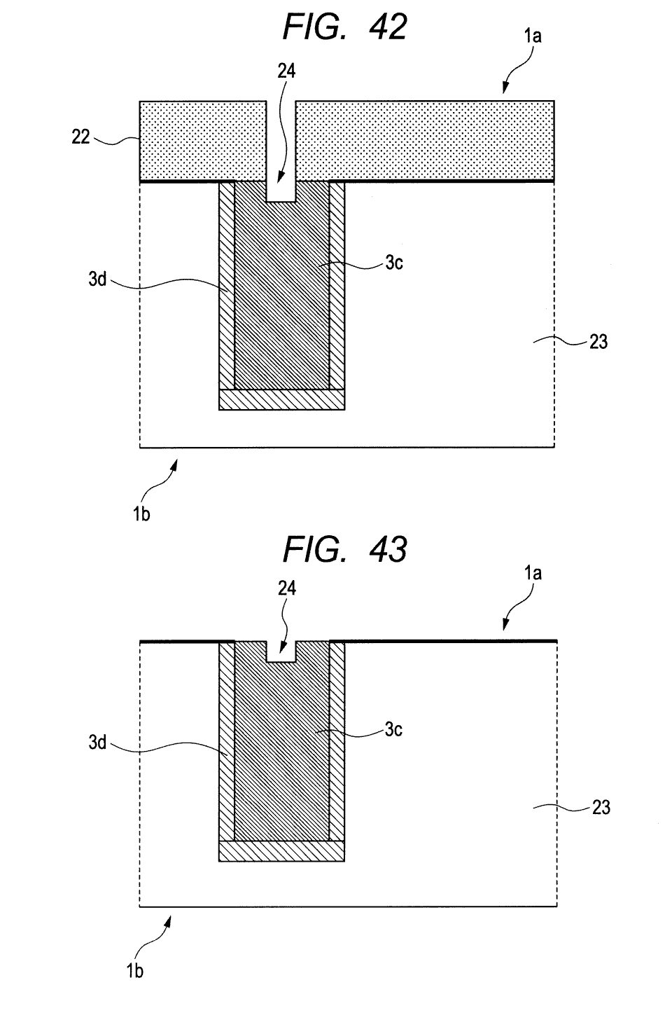

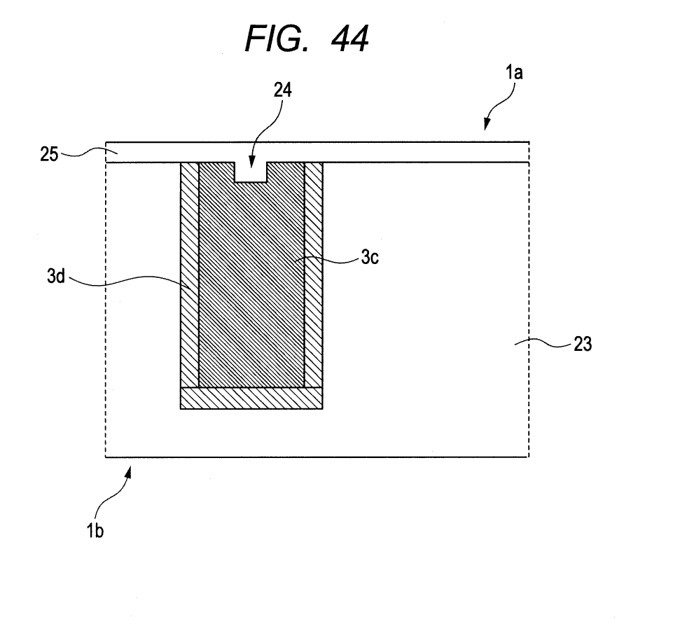

FIG. 39 is a sectional view of a through electrode section (at the time of flattening a surface) showing Modified Example 2 (a recess part is formed by lithography) of a through electrode top end structure and the process thereof common to the embodiments of the present application. FIG. 40 is a top view of the periphery of a through electrode section (at the time of forming a resist film for processing a recess part) showing Modified Example 2 (a recess part is formed by lithography) of a through electrode top end structure and the process thereof common to the embodiments of the present application. FIG. 41 is a sectional view of a through electrode section (at the time of forming a resist film for processing a recess part, corresponding to the section taken on line A-A′ in FIG. 40) showing Modified Example 2 (a recess part is formed by lithography) of a through electrode top end structure and the process thereof common to the embodiments of the present application. FIG. 42 is a sectional view of a through electrode section (at the time of etching a recess part) showing Modified Example 2 (a recess part is formed by lithography) of a through electrode top end structure and the process thereof common to the embodiments of the present application. FIG. 43 is a sectional view of a through electrode section (at the time of removing a resist film for processing a recess part) showing Modified Example 2 (a recess part is formed by lithography) of a through electrode top end structure and the process thereof common to the embodiments of the present application. FIG. 44 is a sectional view of a through electrode section (at the time of forming a metal diffusion barrier insulation film of a kind of silicon nitride) showing Modified Example 2 (a recess part is formed by lithography) of a through electrode top end structure and the process thereof common to the embodiments of the present application. On the basis of those figures, Modified Example 2 (a recess part is formed by lithography) of a through electrode top end structure common to the embodiments of the present application is explained.

In this example, a recess part 24 is formed after a through electrode section 3 is embedded and hence explanations are made on the basis of FIG. 39 corresponding to aforesaid section FIG. 37. As shown in FIG. 39, in the case of this example, regular plating by which an ordinary comparatively planar embedding shape can be obtained is applied during copper electrolytic plating shown in FIG. 36 and hence the recess part 24 does not exist after CMP.

Then a resist film 22 (the thickness is about 1 micrometer for example) having an aperture 26 shown in FIG. 40 is patterned by lithography. The section taken on line A-A′ is shown in FIG. 41.

Successively, as shown in FIG. 42, a recess part 24 is formed by using the resist film 22 having the aperture 26 as a mask and applying metal etching. The dimension of the recess 24 is about 5 micrometers in width and about 2 to 5 micrometers in depth. A preferable example of an etching liquid is a mixed liquid of sulfuric acid and hydrogen peroxide.

Successively, as shown in FIG. 43, the no longer necessary resist film 22 is removed.

Successively, as shown in FIG. 44, a metal diffusion barrier insulation film of a kind of silicon nitride 25 is formed by plasma CVD or the like so as to cover the upper face of the semiconductor substrate and the insulation film 23 thereover and the upper face of the through electrode section 3 and fill the interior of the recess section 24.

12. Summary Although the invention established by the present inventors has been specifically explained on the basis of embodiments, it is obvious that the present invention is not limited to the embodiments and various changes may be made without departing from the scope of the invention.

For example, although concrete explanations have been done on the basis of an embedded wiring that uses a metal of a kind of copper as the main wiring material in the above embodiments, it is obvious that the present invention is not limited to the embodiments and a metal of a kind of silver may be used as the main wiring material. Further, although concrete explanations have been done on the basis of the electrode material of the through electrode section that uses a metal of a kind of copper as the main wiring material, it is obvious that the present invention is not limited to the embodiments and a metal of a kind of tungsten or another metal may be used as the main wiring material.

What is claimed is:

1. A semiconductor integrated circuit device comprising:
(a) a semiconductor substrate having a first main surface and a second main surface;
(b) a semiconductor element forming region and a through via forming region formed on the side of the first main surface;
(c) a pre-metal wiring layer formed over the first main surface;
(d) three or more embedded wiring layers formed over the pre-metal wiring layer;
(e) a pad wiring layer formed over the three or more embedded wiring layers;
(f) metal diffusion preventive insulation films formed at a plurality of interfaces over the pre-metal wiring layer and between the embedded wiring layers respectively; and
(g) a through electrode being formed in the through via forming region, at least passing through the pre-metal wiring layer, and reaching the second main surface of the semiconductor substrate,
wherein, at the interfaces, a first insulation film of a kind of silicon nitride is formed as the metal diffusion preventive insulation film at the interface touching the top end of the through electrode, and insulation films of a kind of silicon carbide are formed as the metal diffusion preventive insulation films at the other interfaces respectively.

2. A semiconductor integrated circuit device according to claim 1, wherein the first insulation film is formed in the semiconductor element forming region and the through via forming region.

3. A semiconductor integrated circuit device according to claim 1, wherein the first insulation film is formed in the through via forming region.

4. A semiconductor integrated circuit device according to claim 1, wherein the interface touching the top end of the through electrode is the interface between the pre-metal wiring layer and the three or more embedded wiring layers.

5. A semiconductor integrated circuit device according to claim 2, wherein the interface touching the top end of the through electrode is any one of the interfaces between the three or more embedded wiring layers.

6. A semiconductor integrated circuit device according to claim 5, wherein a predetermined insulation film of a kind of silicon carbide with which the semiconductor element forming region, the through via forming region, and the first insulation film are covered is formed at the interface touching the top end of the through electrode.

7. A semiconductor integrated circuit device according to claim 4, further comprising:
(h) a second insulation film of a kind of silicon nitride formed at the interface between the three or more embedded wiring layers and the pad wiring layer.

8. A semiconductor integrated circuit device according to claim 1, wherein the three or more embedded wiring layers are embedded wiring layers of a kind of copper.

9. A method for producing a semiconductor integrated circuit device comprising:
(a) a semiconductor substrate having a first main surface and a second main surface;
(b) a semiconductor element forming region and a through via forming region formed on the side of the first main surface;
(c) a pre-metal wiring layer being formed over the first main surface and having a pre-metal insulation film and a metal plug embedded into an aperture thereof;
(d) three or more embedded wiring layers being formed over the pre-metal wiring layer and having interlayer insulation films and wirings embedded into the apertures thereof respectively;
(e) a pad wiring layer formed over the three or more embedded wiring layers;
(f) metal diffusion preventive insulation films formed at a plurality of interfaces over the pre-metal wiring layer and between the embedded wiring layers respectively; and
(g) a through electrode being formed in the through via forming region, at least passing through the pre-metal wiring layer, and reaching the second main surface of the semiconductor substrate,
wherein at the interfaces, a first insulation film of a kind of silicon nitride is formed as the metal diffusion preventive insulation film at the interface touching the top end of the through electrode, and insulation films of a kind of silicon carbide are formed as the metal diffusion preventive insulation films at the other interfaces respectively, and
wherein an electrode that is to be the through electrode is embedded after the insulation films of the wiring layers below the interface touching the top end of the through electrode are formed and before the wiring layers above the interface touching the top end of the through electrode are formed.

10. A method for producing a semiconductor integrated circuit device according to claim 9, wherein the first insulation film is formed in the semiconductor element forming region and the through via forming region.

11. A method for producing a semiconductor integrated circuit device according to claim 9, wherein the first insulation film is formed in the through via forming region.

12. A method for producing a semiconductor integrated circuit device according to claim 9, wherein the interface touching the top end of the through electrode is the interface between the pre-metal wiring layer and the lowermost layer in the three or more embedded wiring layers.

13. A method for producing a semiconductor integrated circuit device according to claim 10, wherein the interface touching the top end of the through electrode is any one of the interfaces between the three or more embedded wiring layers.

14. A method for producing a semiconductor integrated circuit device according to claim 13, wherein a predetermined insulation film of a kind of silicon carbide with which the semiconductor element forming region, the through via forming region, and the first insulation film are covered is formed at the interface touching the top end of the through electrode.

15. A method for producing a semiconductor integrated circuit device according to claim 9, further comprising:
(h) a second insulation film of a kind of silicon nitride formed at the interface between the three or more embedded wiring layers and the pad wiring layer.

16. A method for producing a semiconductor integrated circuit device according to claim 9, wherein the formation of the through electrode is after the insulation films of the wiring layers below the interface touching the top end of the through electrode are formed and before apertures are formed in the insulation films of the wiring layers.

17. A semiconductor integrated circuit device comprising:
(a) a semiconductor substrate having a first main surface and a second main surface;
(b) a semiconductor element forming region and a through via forming region formed on the side of the first main surface;
(c) a pre-metal wiring layer formed over the first main surface;
(d) three or more embedded wiring layers formed over the pre-metal wiring layer;
(e) a pad wiring layer formed over the three or more embedded wiring layers;
(f) metal diffusion preventive insulation films of a kind of silicon carbide formed at a plurality of interfaces between the embedded wiring layers respectively;
(g) a through electrode being formed in the through via forming region, passing through the pre-metal wiring layer, and reaching the second main surface of the semiconductor substrate; and
(h) a wiring pattern belonging to the lowermost layer in the three or more embedded wiring layers with which the top end of the through electrode is completely covered,
wherein a plane area of the wiring pattern is larger than a plane area of the through electrode and an upper surface of the through electrode is completely covered with a barrier metal of the wiring pattern.

18. A method for producing a semiconductor integrated circuit device comprising:
(a) a semiconductor substrate having a first main surface and a second main surface;
(b) a semiconductor element forming region and a through via forming region formed on the side of the first main surface;
(c) a pre-metal wiring layer formed over the first main surface;
(d) three or more embedded wiring layers formed over the pre-metal wiring layer;
(e) a pad wiring layer formed over the three or more embedded wiring layers;
(f) first metal diffusion preventive insulation films of a kind of silicon carbide formed at a plurality of interfaces between the embedded wiring layers respectively;
(g) a through electrode being formed in the through via forming region, passing through the three or more embedded wiring layers and the pre-metal wiring layer, and reaching the second main surface of the semiconductor substrate; and
(h) a second metal diffusion preventive insulation film of a kind of silicon nitride formed at the interface between the three or more embedded wiring layers and the pad wiring layer,
wherein the second metal diffusion preventive insulation film is formed at a film forming temperature in the range of 250° C. to 300° C. by plasma CVD.

19. A method for producing a semiconductor integrated circuit device comprising:
(a) a semiconductor substrate having a first main surface and a second main surface;
(b) a semiconductor element forming region and a through via forming region formed on the side of the first main surface;
(c) a pre-metal wiring layer formed over the first main surface;
(d) three or more embedded wiring layers formed over the pre-metal wiring layer;
(e) a pad wiring layer formed over the three or more embedded wiring layers;
(f) metal diffusion preventive insulation films of a kind of silicon carbide formed at a plurality of interfaces between the embedded wiring layers respectively;
(g) a through electrode being formed in the through via forming region, passing through the pre-metal wiring layer, and reaching the second main surface of the semiconductor substrate; and
(h) a recess part formed at un upper surface of the through electrode,
wherein the recess part is formed when the through electrode is embedded by plating.

20. A method for producing a semiconductor integrated circuit device comprising:
(a) a semiconductor substrate having a first main surface and a second main surface;
(b) a semiconductor element forming region and a through via forming region formed on the side of the first main surface;
(c) a pre-metal wiring layer formed over the first main surface;
(d) three or more embedded wiring layers formed over the pre-metal wiring layer;
(e) a pad wiring layer formed over the three or more embedded wiring layers;
(f) metal diffusion preventive insulation films of a kind of silicon carbide formed at a plurality of interfaces between the embedded wiring layers respectively;
(g) a through electrode being formed in the through via forming region, passing through the pre-metal wiring layer, and reaching the second main surface of the semiconductor substrate; and
(h) a recess part formed at an upper surface of the through electrode,
wherein the recess part is formed by etching the through electrode while a resist film is used as a mask.
